(19) United States
(12) Patent Application Publication
(10) Pub. No.: US 2025/0081465 A1
(43) Pub. Date: Mar. 6, 2025

(54) SEMICONDUCTOR MEMORY DEVICE

(71) Applicant: Kioxia Corporation, Tokyo (JP)

(72) Inventors: Hiroyuki KUTSUKAKE, Kuwana Mie (JP); Kohei NAKAGAMI, Yokkaichi Mie (JP)

(21) Appl. No.: 18/820,075

(22) Filed: Aug. 29, 2024

(30) Foreign Application Priority Data
Aug. 30, 2023 (JP) 2023-140398

(51) Int. Cl. H10B 43/35; H01L 23/528; H01L 29/49; H10B 43/10

(52) U.S. Cl. CPC H10B 43/35; H01L 23/5283; H10B 43/10; H10D 64/668

(57) ABSTRACT

A semiconductor memory device includes a semiconductor substrate that includes first, second, and third regions spaced apart from each other in a first direction on a well region; first and second conductive layers that are spaced apart in the first direction; a first contact connected to the first region and passing through a first opening through the first conductive layer; a second contact connected to the third region and passing through a second opening through the second conductive layer; and third and fourth conductive layers that are between the first and second conductive layers and are spaced apart from each other in the first direction. The first conductive layer and the first contact are connected to each other to be at substantially the same potential, and the second conductive layer and the second contact are connected to each other to be at substantially the same potential.

### CROSS-REFERENCE TO RELATED APPLICATION(S)

This application is based upon and claims the benefit of priority from Japanese Patent Application No. 2023-140398, filed Aug. 30, 2023, the entire contents of which are incorporated herein by reference.

### FIELD

Embodiments described herein relate generally to a semiconductor memory device.

### BACKGROUND

A NAND flash memory is known as a semiconductor memory device capable of storing data in a nonvolatile manner. In a semiconductor memory device such as a NAND flash memory, a three-dimensional memory structure has been adopted for high integration and large capacity.

### DESCRIPTION OF THE DRAWINGS

FIG. 1 is a block diagram showing an example of the configuration of a memory system including a semiconductor memory device according to an embodiment.

FIG. 2 is a circuit diagram showing an example of a circuit configuration of a memory cell array in the semiconductor memory device according to the embodiment.

FIG. 3 is a cross-sectional view showing an example of a cross-sectional structure of the semiconductor memory device according to the embodiment.

FIG. 4 is a circuit diagram showing an example of a configuration of a row decoder module, a driver module, and a memory cell array of the semiconductor memory device according to the embodiment.

FIG. 5 is a circuit diagram showing an example of a configuration of a block decoder provided in the semiconductor memory device according to the embodiment.

FIG. 6 is a plan view showing an example of a planar structure of the row decoder module of the semiconductor memory device according to the embodiment.

FIG. 7 is a plan view showing an example of a planar structure of a transfer transistor provided in the semiconductor memory device according to the embodiment.

FIG. 8 is a cross-sectional view taken along line VIII-VIII of FIG. 7 and shows an example of a cross-sectional structure of the transfer transistor provided in the semiconductor memory device according to the embodiment.

FIG. 9 is a cross-sectional view taken along line IX-IX of FIG. 7 and shows an example of a cross-sectional structure of the transfer transistor provided in the semiconductor memory device according to the embodiment.

FIG. 10 is a cross-sectional view showing an example of a structure during manufacturing of the transfer transistor provided in the semiconductor memory device according to the embodiment.

FIG. 11 is a cross-sectional view showing an example of a structure during manufacturing of the transfer transistor provided in the semiconductor memory device according to the embodiment.

FIG. 12 is a plan view showing an example of a planar structure of a transfer transistor provided in the semiconductor memory device according to a first modification example.

FIG. 13 is a graph showing an example of a surface breakdown voltage of the transfer transistor according to the first modification example.

FIGS. 14A and 14B are each a cross-sectional view taken along line XIV-XIV of FIG. 12 and shows an example of a cross-sectional structure of the transfer transistor provided in the semiconductor memory device according to the first modification example.

FIG. 14C is an enlarged cross-sectional view of a one-dot chain line frame of FIG. 14A.

FIG. 14D is an enlarged cross-sectional view of a one-dot chain line frame of FIG. 14B.

FIG. 15 is a graph showing an example of an on-current of the transfer transistor according to the first modification example.

FIG. 16 is a plan view showing an example of a planar structure of a transfer transistor provided in the semiconductor memory device according to a second modification example.

FIG. 17 is a cross-sectional view taken along line XVII-XVII of FIG. 16 and shows an example of a cross-sectional structure of the transfer transistor provided in the semiconductor memory device according to the second modification example.

FIG. 18 is a cross-sectional view taken along line XVIII-XVIII of FIG. 16 and shows an example of a cross-sectional structure of the transfer transistor provided in the semiconductor memory device according to the second modification example.

FIG. 19 is a plan view showing an example of a planar structure of the transfer transistor provided in a semiconductor memory device according to a third modification example.

FIG. 20 is a cross-sectional view taken along line XX-XX of FIG. 19 and shows an example of a cross-sectional structure of the transfer transistor provided in the semiconductor memory device according to the third modification example.

FIG. 21 is a plan view showing an example of a planar structure of a transfer transistor provided in the semiconductor memory device according to a fourth modification example.

FIG. 22 is a cross-sectional view taken along line XXII-XXII of FIG. 21 and shows an example of a cross-sectional structure of the transfer transistor provided in the semiconductor memory device according to the fourth modification example.

FIG. 23 is a plan view showing an example of a planar structure of a transfer transistor provided in the semiconductor memory device according to a fifth modification example.

FIG. 24 is a cross-sectional view taken along line XXIV-XXIV of FIG. 23 and shows an example of a cross-sectional structure of the transfer transistor provided in the semiconductor memory device according to the fifth modification example.

FIG. 25 is a plan view showing an example of a planar structure of a transfer transistor provided in the semiconductor memory device according to a sixth modification example.

### DETAILED DESCRIPTION

Embodiments provide a semiconductor memory device that improves reliability.

In general, according to one embodiment, a semiconductor memory device includes a semiconductor substrate that includes a well region of a first conductivity-type and first, second, and third regions of a second conductivity-type arranged in this order and spaced apart from each other in a first direction in this order on the well region, wherein each of the first, second, and third regions is a source region or a drain region; a first conductive layer that is provided above the well region and has a first opening; a second conductive layer that is provided above the well region, has a second opening, and is spaced apart from the first conductive layer in the first direction; a first contact that is connected to the first region and passes through the first opening; a second contact that is connected to the third region and passes through the second opening; a first memory cell that is connected to the first contact; a second memory cell that is connected to the second contact; and a third conductive layer and a fourth conductive layer that are provided between the first conductive layer and the second conductive layer above the well region, and are spaced apart from each other in the first direction, wherein the third conductive layer is between the first conductive layer and the fourth conductive layer and spaced apart from the first conductive layer, and the fourth conductive layer is between the second conductive layer and the third conductive layer and spaced apart from the second conductive layer. In addition, the first conductive layer and the first contact are connected to each other to be at substantially the same potential, and the second conductive layer and the second contact are connected to each other to be at substantially the same potential.

Hereinafter, embodiments will be described with reference to drawings. The dimensions and ratios depicted in each drawing are not necessarily the same as actual ones.

In the following description, the same reference numerals are added to elements having substantially the same function and configuration. Letters or numerals different from each other may be added to the end of the same reference numerals when specifically distinguishing between elements having similar configurations.

### 1. Embodiment

### 1.1 Configuration

### 1.1.1 Memory System

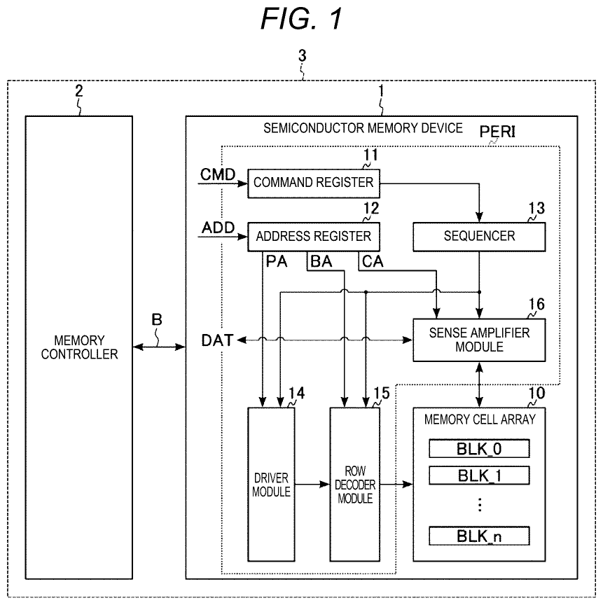

FIG. 1 is a block diagram showing an example of a configuration of the memory system including the semiconductor memory device according to the embodiment.

A memory system 3 includes a semiconductor memory device 1 and a memory controller 2.

The memory system 3 is, for example, a memory card such as an SD® card, a universal flash storage (UFS), or a solid state drive (SSD). The memory system 3 is configured to be connected to an external host device (not shown).

The memory controller 2 is configured with, for example, an integrated circuit such as a system-on-a-chip (SoC). The memory controller 2 controls the semiconductor memory device 1 based on a request from the host device. Specifically, for example, the memory controller 2 writes data requested to be written by the host device to the semiconductor memory device 1. The memory controller 2 reads data requested to be read from the host device from the semiconductor memory device 1 and transmits the data to the host device.

The semiconductor memory device 1 is, for example, a NAND flash memory. The semiconductor memory device 1 stores data in a nonvolatile manner. The semiconductor memory device 1 is connected to the memory controller 2 through a NAND bus B.

The NAND bus B is, for example, a bus having a single data rate (SDR) interface, a toggle double data rate (DDR) interface, or an open NAND flash interface (ONFI).

### 1.1.2 Semiconductor Memory Device

An internal configuration of the semiconductor memory device 1 according to the embodiment will be described with reference to a block diagram shown in FIG. 1. The semiconductor memory device 1 includes, for example, a memory cell array 10 and a peripheral circuit PERI. The peripheral circuit PERI includes a command register 11, an address register 12, a sequencer 13, a driver module 14, a row decoder module 15, and a sense amplifier module 16.

The memory cell array 10 includes a plurality of blocks BLK0 to BLKn (n is an integer equal to or larger than 1). The block BLK is a set of a plurality of memory cell transistors capable of storing data in a non-volatile manner, and is used, for example, as an erasing unit for data. A plurality of bit lines and a plurality of word lines are provided in the memory cell array 10. One memory cell transistor is associated with, for example, one bit line and one word line.

The command register 11 stores a command CMD received from the memory controller 2 by the semiconductor memory device 1. The command CMD includes, for example, an instruction to cause the sequencer 13 to perform a read operation, a write operation, an erasing operation, and the like.

The address register 12 stores address information ADD received from the memory controller 2 by the semiconductor memory device 1. The address information ADD includes, for example, a page address PA, a block address BA, and a column address CA. For example, the page address PA, the block address BA, and the column address CA are used to select the word line, the block BLK, and the bit line, respectively.

The sequencer 13 controls the operation of the semiconductor memory device 1 as a whole. For example, the sequencer 13 controls the driver module 14, the row decoder module 15, the sense amplifier module 16, and the like based on the command CMD stored in the command register 11 to execute a read operation, a write operation, an erasing operation, and the like.

The driver module 14 generates voltages used in the read operation, the write operation, the erasing operation, and the like. The driver module 14 applies the generated voltage to a signal line corresponding to the selected word line, based on the page address PA stored in the address register 12, for example.

The row decoder module 15 selects one block BLK in the corresponding memory cell array 10 based on the block address BA stored in the address register 12. The row decoder module 15 transfers, for example, the voltage applied to the signal line corresponding to the selected word line, to the selected word line in the selected block BLK.

The sense amplifier module 16 transfers the data DAT between the memory controller 2 and the memory cell array 10. The data DAT includes write data and read data. More specifically, the sense amplifier module 16 transfers the write data received from the memory controller 2 to the memory cell array 10 in the write operation. In addition, the sense amplifier module 16 executes determination of data stored in the memory cell transistor based on the voltage of the bit line in the read operation. The sense amplifier module 16 transfers a result of the determination as read data to the memory controller 2.

### 1.1.3 Circuit Configuration of Memory Cell Array

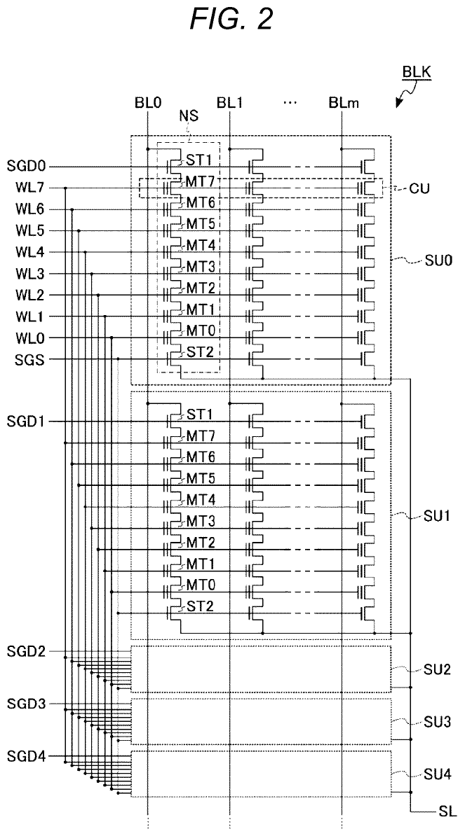

FIG. 2 is a circuit diagram showing the example of the circuit configuration of the memory cell array in the semiconductor memory device according to the embodiment. FIG. 2 shows one block BLK among a plurality of blocks BLK in the memory cell array 10. In the example shown in FIG. 2, the block BLK includes, for example, five string units SU0 to SU4.

Each string unit SU includes a plurality of NAND strings NS associated with bit lines BL0 to BLm (where m is an integer of 1 or more). Each NAND string NS includes, for example, memory cell transistors MT0 to MT7 and select transistors ST1 and ST2. Each of the memory cell transistors MT0 to MT7 includes a control gate and a charge storage layer, and stores data in a non-volatile manner. Each of the select transistors ST1 and ST2 is used for selecting the string unit SU when performing the various operations. In the following description, the memory cell transistors MT0 to MT7 are also referred to as memory cell transistors MT, respectively.

The memory cell transistors MT0 to MT7 in each NAND string NS are connected in series. One end of the select transistor ST1 is connected to the associated bit line BL, and the other end of the select transistor ST1 is connected to one ends of the memory cell transistors MT0 to MT7 connected in series. One end of the select transistor ST2 is connected to the other ends of the memory cell transistors MT0 to MT7 connected in series. The other end of the select transistor ST2 is connected to a source line SL.

The control gates of the memory cell transistors MT0 to MT7 in the same block BLK are connected to word lines WL0 to WL7, respectively. The gates of the select transistors ST1 in the respective string units SU0 to SU4 are connected to select gate lines SGD0 to SGD4. Meanwhile, gates of the plurality of select transistors ST2 are commonly connected to a select gate line SGS. However, the embodiment is not limited to this, and the gates of the plurality of select transistors ST2 may be connected to a plurality of select gate lines that are different for each string unit SU, respectively. In the following description, when the word lines WL0 to WL7 are not distinguished from each other, the word lines WL0 to WL7 are simply referred to as a word line WL. Further, when the select gate lines SGD0 to SGD4 are not distinguished from each other, the select gate lines SGD0 to SGD4 are simply referred to as a select gate line SGD.

Each of the bit lines BL0 to BLm commonly connects one NAND string NS provided in each string unit SU across the plurality of blocks BLK. Each set of the word lines WL0 to WL7 is provided separately for each block BLK. The source line SL is shared among, for example, the plurality of blocks BLK.

A set of a plurality of memory cell transistors MT connected to a common word line WL in the same string unit SU is referred to as, for example, a “cell unit CU”. For example, a storage capacity of the cell unit CU that includes the memory cell transistors MT, each of which stores one bit data, is defined as “one page data”. The cell unit CU may have a storage capacity equal to or larger than two page data according to the number of bits of data stored in the memory cell transistor MT.

The circuit configuration of the memory cell array 10 provided in the semiconductor memory device 1 according to the embodiment is not limited to the configuration described above. For example, each block BLK may be designed to include any number of string units SU. Each NAND string NS may be designed to include any number of memory cell transistors MT and select transistors ST1 and ST2.

### 1.1.4 Cross-Sectional Structure of Semiconductor Memory Device

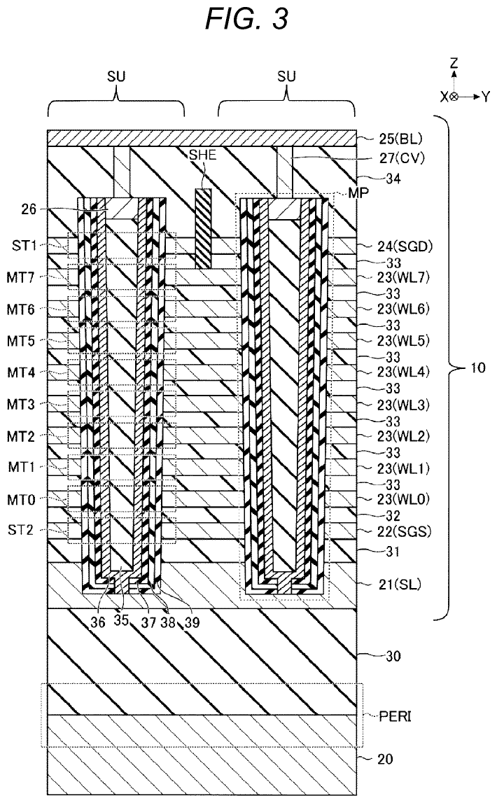

Next, a cross-sectional structure of the semiconductor memory device 1 according to the embodiment will be described with reference to FIG. 3. FIG. 3 is a cross-sectional view showing an example of a cross-sectional structure of the semiconductor memory device according to the embodiment. FIG. 3 shows a cross-sectional structure including two string units SU among five string units SU provided in one block BLK.

In the drawings referred to below, an X direction corresponds to the extending direction of the word line WL, a Y direction corresponds to the extending direction of the bit line BL, and a Z direction corresponds to the vertical direction with respect to the surface of the semiconductor substrate on which the semiconductor memory device 1 is formed.

The memory cell array 10 includes a conductive layer 21, a conductive layer 22, a conductive layer 24, and a conductive layer 25 provided above the semiconductor substrate 20, a plurality of conductive layers 23, and a plurality of memory pillars MP (only two are shown in the drawing in FIG. 3). In the following description, a direction in which the memory cell array 10 is provided with respect to the semiconductor substrate 20 is referred to as an upward direction. Further, the opposite direction is referred to as a downward direction.

An insulator layer 30 is provided on the semiconductor substrate 20. The insulator layer 30 includes a peripheral circuit PERI corresponding to, for example, the row decoder module 15 or the like.

The conductive layer 21 is stacked on the insulator layer 30. The conductive layer 21 is formed, for example, in a plate shape extending along the XY plane. The conductive layer 21 is used as the source line SL. The conductive layer 21 is made of a conductive material, and a metal material such as an N-type semiconductor to which an impurity is added, titanium nitride (TiN), tantalum nitride (TaN), aluminum (Al), and a stacked film of tantalum nitride (TaN) and tantalum (Ta), a stacked film of titanium (Ti), titanium nitride (TiN), and tungsten (W), or a stacked film of titanium nitride (TiN) and tungsten silicide (WSi) is used. In addition, the conductive layer 21 may have a stacked structure of a semiconductor and a metal material, such as a stacked film of titanium nitride (TiN), tungsten silicide (WSi), and poly-Si.

An insulator layer 31 is provided on the conductive layer 21. The conductive layer 22 is stacked on the insulator layer 31. The conductive layer 22 is formed, for example, in a plate shape extending along the XY plane. The conductive layer 22 is used as the select gate line SGS. The conductive layer 22 contains, for example, tungsten (W).

An insulator layer 32 is provided on the conductive layer 22. Eight conductive layers 23 and eight insulator layers 33 are alternately stacked on the insulator layer 32. The conductive layer 23 is formed, for example, in a plate shape extending along the XY plane. The eight stacked conductive layers 23 are used as word lines WL0 to WL7, respectively, from the side of the conductive layer 21. The conductive layer 23 contains, for example, tungsten (W).

The conductive layer 24 and the insulator layer 34 are stacked in this order on the top insulator layer 33. The conductive layer 24 is formed, for example, in a plate shape extending along the XY plane. The stacked conductive layer 24 is used as the select gate line SGD. The conductive layer 24 contains, for example, tungsten (W). The conductive layer 24 is electrically separated for each string unit SU, for example, by a slit SHE.

An insulator layer 34 is provided on the conductive layer 24. The conductive layer 25 is provided on the insulator layer 34. The conductive layer 25 is formed in a line shape extending in the Y direction, for example, and functions as a bit line BL. The conductive layer 25 contains, for example, copper (Cu).

The plurality of memory pillars MP extend along the Z direction below the conductive layer 25 and penetrate the conductive layers 22 and 24 and the plurality of conductive layers 23. In addition, a bottom portion of each of the memory pillars MP is located in a lower layer than the insulator layer 31 and is in contact with the conductive layer 21.

Each of memory pillars MP includes, for example, a core member 35, a semiconductor film 36, a tunnel insulating film 37, a charge storage film 38, a block insulating film 39, and a semiconductor portion 26.

The core member 35 is provided, for example, to extend along the Z direction. An upper end of the core member 35 is provided in a layer above the conductive layer 24, and a lower end of the core member 35 is provided in a layer below the conductive layer 22. The core member 35 contains, for example, silicon oxide (SiO₂).

The semiconductor film 36 covers the side surface and the lower surface of the core member 35. An upper end of the semiconductor film 36 reaches a position equal to an upper end position of the core member 35. A lower end of the semiconductor film 36 is in contact with the conductive layer 21. The semiconductor film 36 contains polysilicon, for example.

The tunnel insulating film 37 covers a side surface of the semiconductor film 36. The tunnel insulating film 37 contains, for example, silicon oxide (SiO₂).

The charge storage film 38 covers a side surface of the tunnel insulating film 37. The charge storage film 38 includes, for example, an insulator capable of storing charges. The insulator is, for example, silicon nitride (SiN).

The block insulating film 39 covers a side surface of the charge storage film 38. The block insulating film 39 contains, for example, silicon oxide (SiO₂).

The semiconductor portion 26 is in contact with the semiconductor film 36 and covers the upper end of the core member 35. A conductive layer 27 functioning as a columnar contact CV is provided at an upper end of the semiconductor portion 26. An upper end of the conductive layer 27 is in contact with the conductive layer 25.

In the structure of the memory pillar MP described above, a portion where the memory pillar MP and the conductive layer 22 intersect functions as the select transistor ST2. A portion, at which the memory pillar MP and the conductive layer 23 intersect with each other, functions as the memory cell transistor MT. In addition, a portion where the memory pillar MP and the conductive layer 24 intersect functions as the select transistor ST1. Further, the semiconductor film 36 functions as channels of the memory cell transistors MT0 to MT7 and the select transistors ST1 and ST2. The charge storage film 38 functions as a charge storage layer of the memory cell transistor MT.

### 1.1.5 Row Decoder Module

Next, a configuration example of the row decoder module 15 provided in the peripheral circuit PERI will be described.

### 1.1.5.1 Overall Configuration

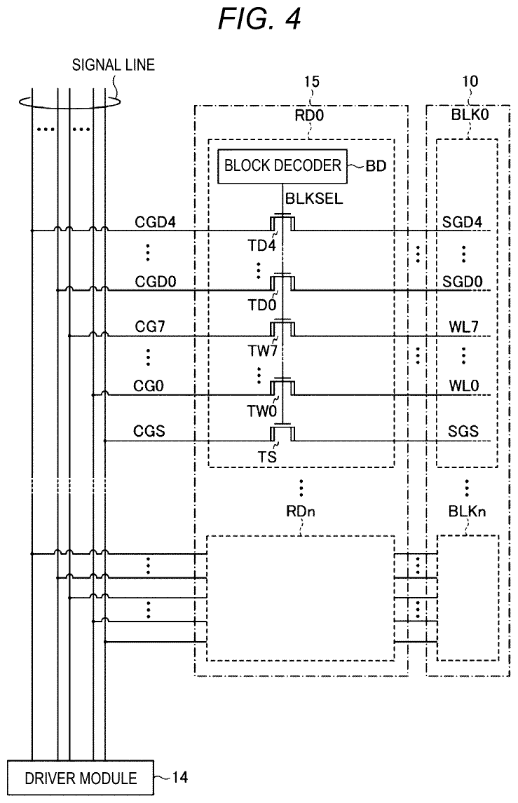

The overall configuration of the row decoder module 15 will be described with reference to FIG. 4. FIG. 4 is a circuit diagram for illustrating an example of a configuration of the row decoder module, the driver module, and the memory cell array of the semiconductor memory device according to the embodiment.

The row decoder module 15 includes row decoders RD0 to RDn. The row decoders RD0 to RDn are each used for selecting a block BLK. The row decoders RD0 to RDn are associated with the blocks BLK0 to BLKn, respectively.

Each row decoder RD includes, for example, a block decoder BD and transfer transistors TW0 to TW7, TS, and TD0 to TD4. The transfer transistors TW0 to TW7, TS, and TD0 to TD4 are, for example, N-channel type metal-oxide-semiconductor field effect transistors (MOSFETs) having a high breakdown voltage. The transfer transistors TW0 to TW7 are associated with the word lines WL0 to WL7, respectively. In the following description, when the transfer transistors TW0 to TW7 are not distinguished from each other, the transfer transistors TW0 to TW7 are simply referred to as transfer transistors TW. The transfer transistors TS and TD0 to TD4 are associated with the select gate lines SGS and SGD0 to SGD4, respectively. In the following description, when the transfer transistors TD0 to TD4 are not distinguished from each other, the transfer transistors TD0 to TD4 are simply referred to as transfer transistors TD. The high breakdown voltage MOSFET is a MOSFET having a physical film thickness of a gate insulating film of 10 nm or more. The voltage between the gate and the source of the N-channel type MOSFET having a high breakdown voltage may be, for example, 10 V or more.

The block decoder BD decodes the block address BA. The block decoder BD applies a voltage of an “H (High)” level and a voltage of an “L (Low)” level to a transfer gate line BLKSEL, for example, based on a result of the decoding.

The transfer transistors TW0 to TW7, TS, and TD0 to TD4 connect the blocks BLK corresponding to the driver module 14 to the signal lines CG0 to CG7, CGS, and CGD0 to CGD4, respectively. In the following description, when the signal lines CG0 to CG7, CGS, and CGD0 to CGD4 are not distinguished from each other, the signal lines CG0 to CG7, CGS, and CGD0 to CGD4 are simply referred to as the signal lines CG.

More specifically, in each row decoder RD, the gate of the transfer transistor TD is connected to the transfer gate line BLKSEL. A first end of each transfer transistor TD is connected to the driver module 14 through the corresponding signal line CG among the signal lines CGD0 to CGD4. A second end of the transfer transistor TD is connected to the corresponding select gate line SGD among the select gate lines SGD0 to SGD4.

Each of the gates of the transfer transistors TW is connected to a transfer gate line BLKSEL. A first end of each transfer transistor TW is connected to the driver module 14 through the corresponding signal line CG among the signal lines CG0 to CG7. A second end of each transfer transistor TW is connected to the corresponding word line WL among the word lines WL0 to WL7.

The gate of the transfer transistor TS is connected to a transfer gate line BLKSEL. A first end of the transfer transistor TS is connected to the driver module 14 through the signal line CGS. A second end of the transfer transistor TS is connected to the select gate line SGS.

When a voltage of an “H” level is applied to the transfer gate line BLKSEL, the transfer transistors TW, TS, and TD are turned on. Thereby, the voltage of each of the signal lines CG0 to CG7, CGS, and CGD0 to CGD4 is transferred to the word lines WL0 to WL7, the select gate line SGS, and the select gate lines SGD0 to SGD4, respectively, through the transfer transistors TW0 to TW7, TS, and TD0 to TD4. When a voltage of an “L” level is applied to the transfer gate line BLKSEL, the transfer transistors TW, TS, and TD are in an off state.

### 1.1.5.2 Block Decoder

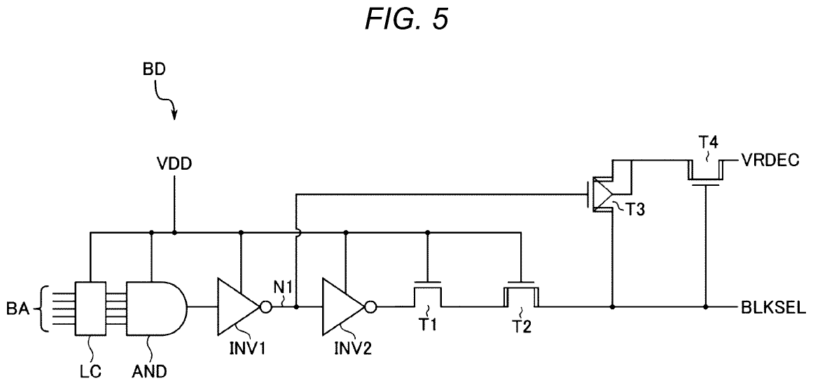

The configuration of the block decoder BD provided in each row decoder RD will be described with reference to FIG. 5. FIG. 5 is a circuit diagram for illustrating an example of a configuration of the block decoder provided in the semiconductor memory device according to the embodiment.

As shown in FIG. 5, the block decoder BD includes a logic circuit LC, a logical product circuit AND, inverters INV1 and INV2, and transistors T1, T2, T3, and T4. The transistors T1, T2, and T4 are N-channel type MOSFETs. The transistor T3 is a P-channel type MOSFET. The transistors T2, T3, and T4 are high breakdown voltage MOSFETs having a physical film thickness of the gate insulating film greater than that of the transistor T1. The physical film thickness of the gate insulating film of each of the transistors T2, T3, and T4 is, for example, 10 nm or more. In addition, the gate and source voltage of each of the transistors T2, T3, and T4 may be, for example, 10 V or more. Meanwhile, the physical film thickness of the gate insulating film of the transistor T1 is, for example, thinner than 10 nm. In addition, the gate and source voltage of the transistor T1 is, for example, lower than 10 V.

The block address BA is input from the address register 12 to the first end of the logic circuit LC. For example, a power supply voltage VDD is applied to a second end of the logic circuit LC. The logic circuit LC is driven by a power supply voltage VDD. A signal based on the block address BA is output from the third end of the logic circuit LC. When the block address BA input to the logic circuit LC is the block address BA assigned to the block BLK corresponding to the logic circuit LC, a signal of an “H” level is output from the third end of the logic circuit LC. When the block address BA input to the logic circuit LC is not the block address BA assigned to the block BLK corresponding to the logic circuit LC, a signal of an “L” level is output from the third end of the logic circuit LC.

A first end of the logical product circuit AND is connected to a third end of the logic circuit LC. For example, a power supply voltage VDD is applied to a second end of the logical product circuit AND. The logical product circuit AND is driven by the power supply voltage VDD. A signal based on a logical product operation of a signal output from the third end of the logic circuit LC is output from the third end of the logical product circuit AND.

A first end of the inverter INV1 is connected to a third end of the logical product circuit AND. For example, a power supply voltage VDD is applied to the second end of the inverter INV1. The inverter INV1 is driven by a power supply voltage VDD. A third end of the inverter INV1 is connected to the node N1. An inverted signal, which is a signal obtained by inverting a signal output from the third end of the logical product circuit AND, is output from the third end of the inverter INV1.

A first end of the inverter INV2 is connected to the node N1. For example, a power supply voltage VDD is applied to the second end of the inverter INV2. The inverter INV2 is driven by a power supply voltage VDD. An inverted signal, which is a signal obtained by inverting a signal output from the third end of the inverter INV1, is output from the third end of the inverter INV2.

A first end of the transistor T1 is connected to a third end of the inverter INV2. The power supply voltage VDD is applied to the gate of the transistor T1. A second end of the transistor T1 is connected to the transistor T2.

A first end of the transistor T2 is connected to the second end of the transistor T1. The power supply voltage VDD is applied to the gate of the transistor T2. A second end of the transistor T2 is connected to the transfer gate line BLKSEL.

A first end of the transistor T3 is connected to the transfer gate line BLKSEL. The gate of the transistor T3 is connected to the node N1. A second end of the transistor T3 is connected to a transistor T4 and a back gate of the transistor T3.

A first end of the transistor T4 is connected to the second end of the transistor T3 and the back gate of the transistor T3. A gate of the transistor T4 is connected to the transfer gate line BLKSEL. A second end of the transistor T4 is connected to the node VRDEC. The node VRDEC is applied with a high voltage that is transferred to the transfer gate line BLKSEL through the transistors T3 and T4, and that is set to be transferred to the corresponding signal lines CG by the transfer transistors TW, TS, and TD.

With the above configuration, the block decoder BD outputs a signal of an “H” level to the transfer gate line BLKSEL when the corresponding block BLK is selected. The block decoder BD outputs a signal of an “L” level to the transfer gate line BLKSEL when the corresponding block BLK is not selected.

### 1.1.5.3 Planar Configuration of Row Decoder Module

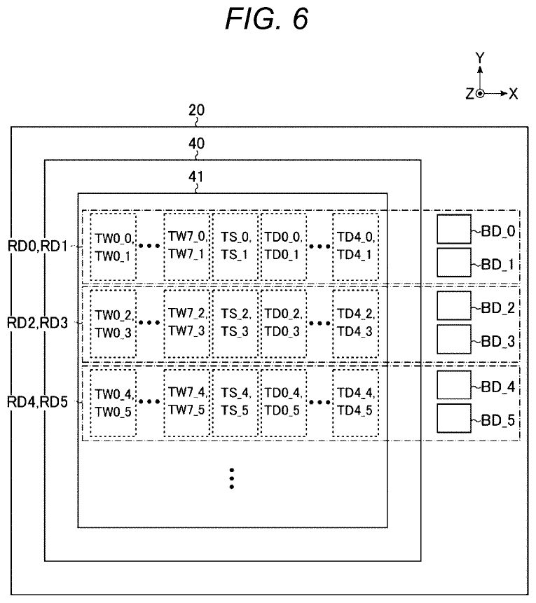

A planar structure of the row decoder module 15 of the semiconductor memory device 1 according to the embodiment will be described with reference to FIG. 6. FIG. 6 is a plan view showing an example of a planar structure of the row decoder module of the semiconductor memory device according to the embodiment. In the following description, the transfer transistors TW0 to TW7, TS, and TD0 to TD4 and the block decoder BD provided in the row decoder RDi are also referred to as transfer transistors TW0_i to TW7_i, TS_i, and TD0_i to TD4_i, and a block decoder BD_i, respectively, where i is an integer of 0 or more and n or less.

The row decoder module 15 is provided on the semiconductor substrate 20.

An N-type well region 40 is provided in the semiconductor substrate 20. The N-type well region 40 is a region containing an N-type impurity. The N-type well region 40 is provided in, for example, a rectangular region.

A P-type well region 41 is provided in the N-type well region 40. The P-type well region 41 is a region containing a P-type impurity. The P-type well region 41 is provided in, for example, a rectangular region.

A set of row decoders RD(2j) and RD (2j+1) are provided in, for example, a rectangular region, where j is an integer of 0 or more and (n−1)/2 or less.

In addition, a set including the row decoders RD0 and RD1, a set including the row decoders RD2 and RD3, a set including the row decoders RD4 and RD5, . . . are arranged in this order, for example, along the Y direction.

In the set including the row decoders RD(2j) and RD(2j+1), the transfer transistors TS_(2j) and TS_(2j+1), TW0_(2j) and TW0_(2j+1), . . . , TW7_(2j) and TW7_(2j+1), TD0_(2j) and TD0_(2j+1), . . . , and TD4_(2j) and TD4_(2j+1) are provided in, for example, the P-type well region 41, respectively.

In the set including the row decoders RD(2j) and RD(2j+1), the block decoders BD_(2j) and BD_(2j+1) are provided, for example, outside the N-type well region 40.

The sets of the plurality of transfer transistors TW_(2j) and TW_(2j+1), the sets of TS_(2j) and TS_(2j+1), and the sets of TD_(2j) and TD_(2j+1) are provided in a matrix shape arranged in each of the X direction and the Y direction, for example.

### 1.1.5.4 Transfer Transistor

A configuration of the transfer transistors TW, TS, and TD provided in the semiconductor memory device 1 according to the embodiment will be described.

### Planar Structure

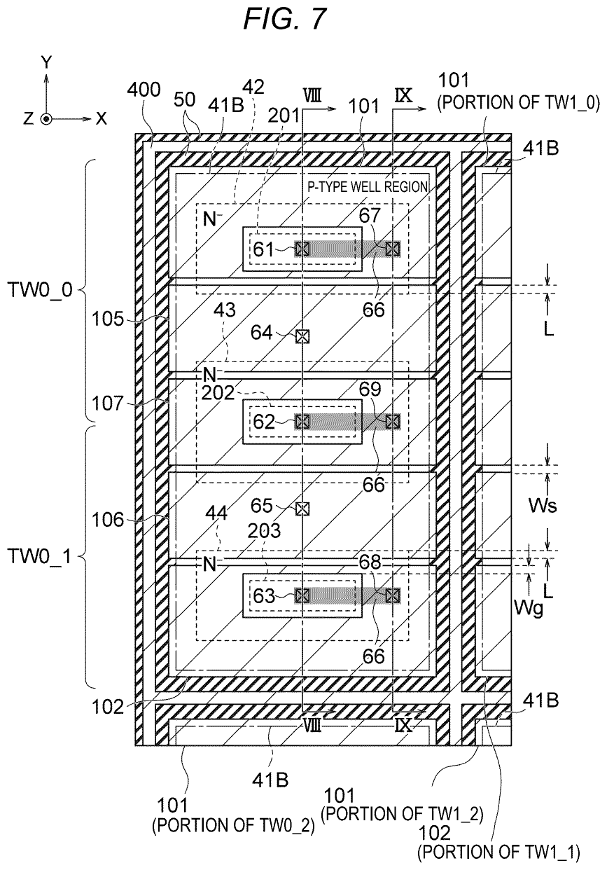

A planar structure of the transfer transistors TW, TS, and TD will be described with reference to FIG. 7. FIG. 7 is a plan view showing an example of a planar structure of a transfer transistor provided in the semiconductor memory device according to the embodiment. In the example shown in FIG. 7, a planar structure mainly including the transfer transistors TW0_0 and TW0_1 shown in FIG. 6 is shown. FIG. 7 also shows a portion of the transfer transistor TW1_0, a portion of the transfer transistor TW1_1, a portion of the transfer transistor TW0_2, and a portion of the transfer transistor TW1_2. The structure of the set including the transfer transistors TW_(2j) and TW_(2j+1), the structure of the set including the transistors TS_(2j) and TS_(2j+1), and the structure of the set including the transistors TD_(2j) and TD_(2j+1) have substantially the same structure as each other. In the following, the structures of the transfer transistors TW0_0 and TW0_1 are mainly described.

The P-type well region 41 is electrically divided into two P-type well regions by an insulator layer 50 that functions as an element separation region, for example. In a plan view, the insulator layer 50 surrounds the P-type well region 41B. The P-type well region 41B is a region surrounded by a one-dot chain line in FIG. 7. The other P-type well region is provided outside a region surrounded by the insulator layer 50 in a region (not shown). In addition, the insulator layer 50 is provided in a lattice shape to separate, for example, a set of a plurality of transfer transistors TW, TS, and TD arranged in a matrix shape.

In the P-type well region 41B, the transfer transistors TW0_0 and TW0_1 are provided in this order along the Y direction. In the following description, among the transfer transistors TW0_0 and TW0_1, an end with which the transfer transistor TW0_0 is provided is designated as one end. In addition, among transfer transistors TW0_0 and TW0_1, an end with which the transfer transistor TW0_1 is provided is designated as the other end.

The N− impurity diffusion regions 42, 43, and 44 are provided in this order to be separated from each other in the Y direction in the P-type well region 41B. The N− impurity diffusion regions 42, 43, and 44 are N-type impurity diffusion regions of phosphorus (P), arsenic (As), or the like.

The electrode 201 is provided in the N− impurity diffusion region 42. The electrode 202 is provided in the N− impurity diffusion region 43. The electrode 203 is provided in the N− impurity diffusion region 44. The region in which the electrodes 201, 202, and 203 are provided is a region surrounded by a broken line in FIG. 7.

The electrode 201 functions as a first end of the transfer transistor TW0_0. The electrode 203 functions as a first end of the transfer transistor TW0_1. The electrode 202 functions as a second end of the transfer transistor TW0_0 and a second end of the transfer transistor TW0_1. As described above, the transfer transistors TW0_0 and TW0_1 share the electrode 202.

The contact 61 is connected on the electrode 201. The contact 61 is connected to the word line WL0 of the block BLK0. The contact 62 is connected on the electrode 202. The contact 62 is connected to the signal line CG0. The contact 63 is connected on the electrode 203. The contact 63 is connected to the word line WL0 of the block BLK1. Although the example shown in FIG. 7 shows a case where the number of contacts provided in each of the electrodes 201, 202, and 203 is one, the present disclosure is not limited thereto. The number of contacts provided in each of the electrodes 201, 202, and 203 may be two or more.

Five electrodes 101, 105, 107, 106, and 102 are provided in this order from one end side toward the other end side in the Y direction above the P-type well region 41B with the gate insulating film interposed therebetween.

The electrode 101 has an opening that surrounds the contact 61. The opening corresponds to a region in which the electrode 201 is provided. A side wall (not shown in FIG. 7) is provided on the side surface of the outer periphery of the electrode 101 and the side surface of the inner periphery of the electrode 101 corresponding to the opening.

In addition, the electrode 101 is connected to the contact 67. The contact 67 is electrically connected to the contact 61 through one of the conductive layers 66. Thereby, the electrode 101 is connected to the contact 61 to be at substantially the same potential as the contact 61.

The electrode 102 has an opening that surrounds the contact 63. The opening corresponds to a region in which the electrode 203 is provided. A side wall (not shown in FIG. 7) is provided on the side surface of the outer periphery of the electrode 102 and the side surface of the inner periphery of the electrode 102 corresponding to the opening.

In addition, the electrode 102 is connected to the contact 68. The contact 68 is electrically connected to the contact 63 through one of the conductive layers 66. Thereby, the electrode 102 is connected to the contact 63 to be at substantially the same potential as the contact 63.

The electrode 105 functions as a gate of the transfer transistor TW0_0. A side wall (not shown in FIG. 7) is provided on the side surface of the outer periphery of the electrode 105.

The electrode 106 functions as a gate of the transfer transistor TW0_1. A side wall (not shown in FIG. 7) is provided on the side surface of the outer periphery of the electrode 106.

The electrode 107 has an opening that surrounds the contact 62. The opening corresponds to a region in which the electrode 202 is provided. A side wall (not shown in FIG. 7) is provided on the side surface of the outer periphery of the electrode 107 and the side surface of the inner periphery of the electrode 107 corresponding to the opening.

Further, the electrode 107 is connected to the contact 69. The contact 69 is electrically connected to the contact 62 through one of the conductive layers 66. Thereby, the electrode 107 is connected to the contact 62 to be at substantially the same potential as the contact 62.

Two adjacent electrodes among the electrodes 101, 102, 105, 106, and 107 are separated from each other so that a slit is formed.

An overlap distance L shown in FIG. 7 indicates a distance in the Y direction in which the electrode 105 and the N− impurity diffusion region 42 overlap with each other when viewed in the Z direction. The overlap distance L is also a distance in the Y direction in which the electrode 106 and the N− impurity diffusion region 44 overlap with each other when viewed in the Z direction. The overlap distance L is, for example, 0.2 μm to 0.6 μm. The overlap distance L may be, for example, a distance that can ensure a breakdown voltage required when being cut off in the write operation and the erasing operation. The width Ws is a slit width in the Y direction between the adjacent electrodes 101, 102, 105, 106, and 107 when viewed in the Z direction. The width Ws is, for example, 0.1 μm to 0.2 μm. The width Wg is a width in the Y direction from an inner periphery of the electrode 105 side of the opening of the electrode 101 to an outer periphery of the electrode 101 on the electrode 105 side when viewed in the Z direction, or a width in the Y direction from an inner periphery of the electrode 106 side of the opening of the electrode 102 to an outer periphery of the electrode 102 on the electrode 106 side. The width Wg is, for example, 0.1 μm to 0.3 μm.

With the configuration of the electrodes 105 and 106 as described above, the electrodes 105 and 106 sandwich the electrode 202 along the Y direction in a plan view.

A contact 64 for applying a voltage to the electrode 105 is provided on the electrode 105. The contact 64 is connected to the transfer gate line BLKSEL of the block BLK0. A contact 65 for applying a voltage to the electrode 106 is provided on the electrode 106. The contact 65 is connected to the transfer gate line BLKSEL of the block BLK1. Although the example shown in FIG. 7 shows a case where the number of contacts provided in each of the electrodes 105 and 106 is one, the present disclosure is not limited thereto. The number of contacts provided in each of the electrodes 105 and 106 may be two or more.

Normally, a voltage higher than or equal to the ground voltage VSS (0 V) is applied to the electrodes 105 and 106 during various operations such as a write operation, a read operation, and an erasing operation.

In a region where the insulator layer 50 is provided, a shield conductive layer 400 is provided on the insulator layer 50, for example, to surround the P-type well region 41B. The shield conductive layer 400 contains, for example, polysilicon. The shield conductive layer 400 may be provided in a lattice shape in the same manner as the insulator layer 50. A side wall (not shown in FIG. 7) is provided on the side surface of the inner and outer peripheries of the shield conductive layer 400.

The shield conductive layer 400 is in a state of being applied with the ground voltage VSS, in a floating state, or in a state of being at the same potential as the P-type well region 41B. The shield conductive layer 400 prevents the generation of a leakage current between the transfer transistors during various operations.

### Cross-Sectional Structure

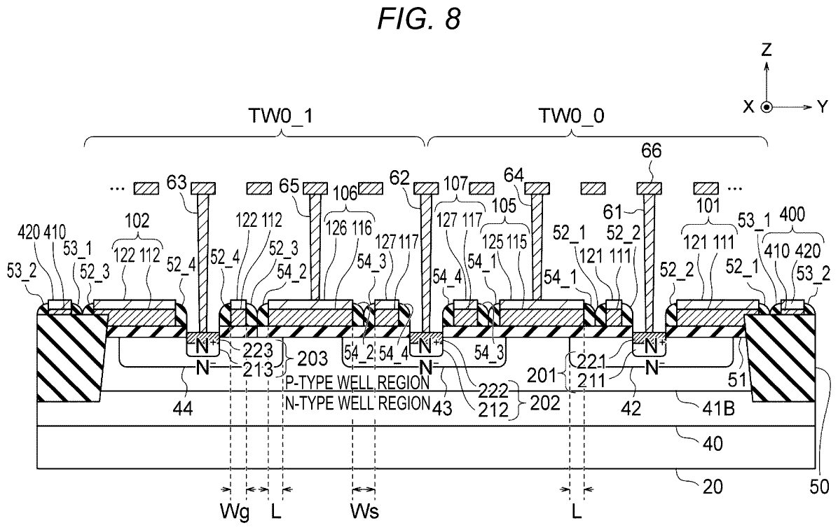

A cross-sectional structure of the transfer transistors TW0_0 and TW0_1 will be described with reference to FIG. 8. FIG. 8 is a cross-sectional view taken along the line VIII-VIII of FIG. 7 and showing an example of a cross-sectional structure of the transfer transistor provided in the semiconductor memory device according to the embodiment. Hereinafter, a structure of the transfer transistor in the cross section shown in FIG. 8 will be described.

An upper end of the insulator layer 50 is provided at a position above an upper end of the P-type well region 41B. A lower end of the insulator layer 50 is provided at a position above a lower end of the N-type well region 40 and below a lower end of the P-type well region 41B.

The lower end of each of the N− impurity diffusion regions 42, 43, and 44 is provided at a position above the lower end of the P-type well region 41B.

The electrode 201 includes an N+ impurity diffusion region 211 and a conductive layer 221. A lower end of the N+ impurity diffusion region 211 is provided at a position above a lower end of the N− impurity diffusion region 42. The N+ impurity diffusion region 211 is an impurity diffusion region that contains N-type impurities such as phosphorus (P) or arsenic (As) at a higher concentration than the N− impurity diffusion region 42. The conductive layer 221 is provided on the upper surface of the N+ impurity diffusion region 211. An upper end of the conductive layer 221 is higher than, for example, an upper end of the N− impurity diffusion region 42. The conductive layer 221 contains, for example, nickel silicide (NiSi), nickel platinum silicide (NiPtSi), and cobalt silicide (CoSi).

The electrode 202 includes an N+ impurity diffusion region 212 and a conductive layer 222. A lower end of the N+ impurity diffusion region 212 is provided at a position above a lower end of the N− impurity diffusion region 43. The N+ impurity diffusion region 212 is an impurity diffusion region that contains N-type impurities such as phosphorus (P) or arsenic (As) at a higher concentration than the N− impurity diffusion region 43. The conductive layer 222 is provided on the upper surface of the N+ impurity diffusion region 212. An upper end of the conductive layer 222 is higher than, for example, an upper end of the N− impurity diffusion region 43. The conductive layer 222 is provided on the upper surface of the N+ impurity diffusion region 212. The conductive layer 222 contains, for example, nickel silicide (NiSi), nickel platinum silicide (NiPtSi), and cobalt silicide (CoSi).

The electrode 203 includes an N+ impurity diffusion region 213 and a conductive layer 223. A lower end of the N+ impurity diffusion region 213 is provided at a position above a lower end of the N− impurity diffusion region 44. The N+ impurity diffusion region 213 is an impurity diffusion region that contains N-type impurities such as phosphorus (P) or arsenic (As) at a higher concentration than the N− impurity diffusion region 44. The conductive layer 223 is provided on the upper surface of the N+ impurity diffusion region 213. An upper end of the conductive layer 223 is higher than, for example, an upper end of the N− impurity diffusion region 44. The conductive layer 223 is provided on the upper surface of the N+ impurity diffusion region 213. The conductive layer 223 contains, for example, nickel silicide (NiSi), nickel platinum silicide (NiPtSi), and cobalt silicide (CoSi).

The gate insulating film 51 is provided on the upper surface of the region of the P-type well region 41B other than the electrodes 201, 202, and 203. An upper end of the gate insulating film 51 is provided at a position below the upper end of the insulator layer 50.

The electrode 101 includes conductive layers 111 and 121. An upper end of the conductive layer 111 is provided at a position above the upper end of the insulator layer 50. The conductive layer 111 is provided on the upper surface of the portion of the gate insulating film 51 provided on the other end side with respect to the electrode 201, on the upper surface of the portion of the gate insulating film 51 provided on the one end side with respect to the electrode 201, and on the upper surface of the portion of the insulator layer 50 provided on the one end side with respect to the P-type well region 41B. The conductive layer 121 is provided on the upper surface of the conductive layer 111. The conductive layer 111 contains, for example, polysilicon. The conductive layer 121 contains, for example, nickel silicide (NiSi), nickel platinum silicide (NiPtSi), and cobalt silicide (CoSi).

The electrode 102 includes conductive layers 112 and 122. An upper end of the conductive layer 112 is provided at a position above the upper end of the insulator layer 50. The conductive layer 112 is provided on the upper surface of the portion of the gate insulating film 51 provided on one end side with respect to the electrode 203, on the upper surface of the portion of the gate insulating film 51 provided on the other end side with respect to the electrode 203, and on the upper surface of the portion of the insulator layer 50 provided on the other end side with respect to the P-type well region 41B. The conductive layer 122 is provided on the upper surface of the conductive layer 112. The conductive layer 112 contains, for example, polysilicon. The conductive layer 122 contains, for example, nickel silicide (NiSi), nickel platinum silicide (NiPtSi), and cobalt silicide (CoSi).

The electrode 105 includes conductive layers 115 and 125. An upper end of the conductive layer 115 is provided at a position above the upper end of the insulator layer 50. The conductive layer 115 is provided on an upper surface of a portion of the gate insulating film 51 provided between the electrode 201 and the electrode 202. The conductive layer 125 is provided on the upper surface of the conductive layer 115. The conductive layer 115 contains, for example, polysilicon. The conductive layer 125 contains, for example, nickel silicide (NiSi), nickel platinum silicide (NiPtSi), and cobalt silicide (CoSi).

The electrode 106 includes conductive layers 116 and 126. An upper end of the conductive layer 116 is provided at a position above the upper end of the insulator layer 50. The conductive layer 116 is provided on an upper surface of a portion of the gate insulating film 51 provided between the electrode 202 and the electrode 203. The conductive layer 126 is provided on the upper surface of the conductive layer 116. The conductive layer 116 contains, for example, polysilicon. The conductive layer 126 contains, for example, nickel silicide (NiSi), nickel platinum silicide (NiPtSi), and cobalt silicide (CoSi).

The electrode 107 includes conductive layers 117 and 127. An upper end of the conductive layer 117 is provided at a position above the upper end of the insulator layer 50. The conductive layer 117 is provided on the upper surface of the portion of the gate insulating film 51 provided on the one end side and the other end side with respect to the electrode 202. The conductive layer 127 is provided on the upper surface of the conductive layer 117. The conductive layer 117 contains, for example, polysilicon. The conductive layer 127 contains, for example, nickel silicide (NiSi), nickel platinum silicide (NiPtSi), and cobalt silicide (CoSi).

The shield conductive layer 400 includes the conductive layers 410 and 420. The conductive layer 410 is provided on the upper surface of the portion of the insulator layer 50 provided on one end side with respect to the P-type well region 41B and on the upper surface of the portion of the insulator layer 50 provided on the other end side with respect to the P-type well region 41B. The conductive layer 420 is provided on the upper surface of the conductive layer 410. The conductive layer 410 contains, for example, polysilicon. The conductive layer 420 contains, for example, nickel silicide (NiSi), nickel platinum silicide (NiPtSi), and cobalt silicide (CoSi).

Side walls 52_1, 52_2, 52_3, and 52_4 are provided on each of the side surfaces of the electrodes 101 and 102. In the following description, when the side walls 52_1, 52_2, 52_3, and 52_4 are not distinguished from each other, the side walls are simply referred to as a side wall 52. An upper end of the side wall 52 is located at a height equal to or lower than an upper end of the electrodes 101 and 102.

The side wall 52_1 includes a first portion and a second portion. A first portion of the side wall 52_1 is provided on the upper surface of the insulator layer 50 to be in contact with one end of the portion of the electrode 101 provided on one end side with respect to the electrode 201 in the Y direction. In addition, the second portion of the side wall 52_1 is provided on the upper surface of the gate insulating film 51 to be in contact with the other end of the portion of the electrode 101 provided on the other end side with respect to the electrode 201 in the Y direction.

The side wall 52_2 includes a first portion and a second portion. A first portion of the side wall 52_2 is provided on the upper surface of the gate insulating film 51 to be in contact with the other end of the portion of the electrode 101 provided on one end side with respect to the electrode 201 in the Y direction. In addition, the second portion of the side wall 52_2 is provided on the upper surface of the gate insulating film 51 to be in contact with one end of the portion of the electrode 101 provided on the other end side with respect to the electrode 201 in the Y direction. A first portion of the side wall 52_2 and a second portion of the side wall 52_2 are adjacent to the electrode 201 along the Y direction.

The side wall 52_3 includes a first portion and a second portion. A first portion of the side wall 52_3 is provided on the upper surface of the gate insulating film 51 to be in contact with one end of the portion of the electrode 102 provided on one end side with respect to the electrode 203 in the Y direction. In addition, the second portion of the side wall 52_3 is provided on the upper surface of the insulator layer 50 to be in contact with the other end of the portion of the electrode 102 provided on the other end side with respect to the electrode 203 in the Y direction.

The side wall 52_4 includes a first portion and a second portion. A first portion of the side wall 52_4 is provided on the upper surface of the gate insulating film 51 to be in contact with the other end of the portion of the electrode 102 provided on one end side with respect to the electrode 203 in the Y direction. In addition, the second portion of the side wall 52_4 is provided on the upper surface of the gate insulating film 51 to be in contact with one end of the portion of the electrode 102 provided on the other end side with respect to the electrode 203 in the Y direction. A first portion of the side wall 52_4 and a second portion of the side wall 52_4 are adjacent to the electrode 203 along the Y direction.

Side walls 53_1 and 53_2 are provided on the side surface of the shield conductive layer 400. In the following description, when the side walls 53_1 and 53_2 are not distinguished from each other, the side walls 53_1 and 53_2 are simply referred to as a side wall 53. An upper end of the side wall 53 is located at a height equal to or less than that of an upper end of the shield conductive layer 400.

The side wall 53_1 includes a first portion and a second portion. A first portion of the side wall 53_1 is provided on the upper surface of the insulator layer 50 to be in contact with the other end of the portion of the shield conductive layer 400 provided on one end side with respect to the P-type well region 41B in the Y direction. A first portion of the side wall 53_1 is adjacent to a first portion of the side wall 52_1 along the Y direction. In addition, the second portion of the side wall 53_1 is provided on the upper surface of the insulator layer 50 so as to be in contact with one end of the portion of the shield conductive layer 400 provided on the other end side of the P-type well region 41B in the Y direction. The second portion of the side wall 53_1 is adjacent to the second portion of the side wall 52_3 along the Y direction.

The side wall 53_2 includes a first portion and a second portion. A first portion of the side wall 53_2 is provided on the upper surface of the insulator layer 50 to be in contact with one end of the portion of the shield conductive layer 400 provided on one end side with respect to the P-type well region 41B in the Y direction. In addition, the second portion of the side wall 53_2 is provided on the upper surface of the insulator layer 50 to be in contact with the other end of the portion of the shield conductive layer 400 provided on the other end side with respect to the P-type well region 41B in the Y direction. For example, the second portion of the side wall 53_2 is adjacent to the side walls provided on the transfer transistors TW0_2 and TW0_3 in the region (not shown) in the Y direction.

Side walls 54_1, 54_2, 54_3, and 54_4 are provided on each of the side surfaces of the electrodes 105, 106, and 107. In the following description, when the side walls 54_1, 54_2, 54_3, and 54_4 are not distinguished from each other, the side walls 54_1, 54_2, 54_3, and 54_4 are simply referred to as a side wall 54. An upper end of the side wall 54 is located at a height equal to or less than an upper end of the electrodes 105, 106, and 107.

The side wall 54_1 includes a first portion and a second portion. A first portion of the side wall 54_1 is provided on the upper surface of the gate insulating film 51 to be in contact with one end of the portion of the electrode 105 in the Y direction. In addition, the second portion of the side wall 54_1 is provided on the upper surface of the gate insulating film 51 to be in contact with the other end of the portion of the electrode 105 in the Y direction.

The side wall 54_2 includes a first portion and a second portion. A first portion of the side wall 54_2 is provided on the upper surface of the gate insulating film 51 to be in contact with one end of the portion of the electrode 106 in the Y direction. In addition, the second portion of the side wall 54_2 is provided on the upper surface of the gate insulating film 51 to be in contact with the other end of the portion of the electrode 106 in the Y direction.

The side wall 54_3 includes a first portion and a second portion. A first portion of the side wall 54_3 is provided on the upper surface of the gate insulating film 51 to be in contact with one end of the portion of the electrode 107 provided on one end side with respect to the electrode 202 in the Y direction. In addition, the second portion of the side wall 54_3 is provided on the upper surface of the gate insulating film 51 to be in contact with the other end of the portion of the electrode 107 provided on the other end side with respect to the electrode 202 in the Y direction.

The side wall 54_4 includes a first portion and a second portion. A first portion of the side wall 54_4 is provided on the upper surface of the gate insulating film 51 to be in contact with the other end of the portion of the electrode 107 provided on one end side with respect to the electrode 202 in the Y direction. In addition, the second portion of the side wall 54_4 is provided on the upper surface of the gate insulating film 51 to be in contact with one end of the portion of the electrode 107 provided on the other end side with respect to the electrode 202 in the Y direction. A first portion of the side wall 54_4 and a second portion of the side wall 54_4 are adjacent to the electrode 202 along the Y direction.

A plurality of conductive layers 66 are provided above the electrodes 101, 102, 105, 106, and 107. Each of the plurality of conductive layers 66 is connected to the corresponding wirings, such as the select gate lines SGS and SGD0 to SGD4 of each of the plurality of blocks BLK, the word lines WL0 to WL7 of each of the plurality of blocks BLK, the transfer gate lines BLKSEL of each of the plurality of row decoders RD, the signal lines CGS, CG0 to CG7, and CGD0 to CGD4, and the like. Each of the plurality of conductive layers 66 is provided in a line shape extending in the X direction, for example, in a region (not shown).

A lower end of the contact 61 is in contact with the conductive layer 221. An upper end of the contact 61 is connected to the word line WL0 of the block BLK0 through the corresponding conductive layer of the plurality of conductive layers 66.

A lower end of the contact 62 is in contact with the conductive layer 222. An upper end of the contact 62 is connected to the signal line CGO through the corresponding conductive layer of the plurality of conductive layers 66.

A lower end of the contact 63 is in contact with the conductive layer 223. An upper end of the contact 63 is connected to the word line WL0 of the block BLK through the corresponding conductive layer of the plurality of conductive layers 66.

A lower end of the contact 64 is in contact with the conductive layer 125. An upper end of the contact 64 is connected to the transfer gate line BLKSEL of the block BLK0 through the corresponding conductive layer of the plurality of conductive layers 66.

A lower end of the contact 65 is in contact with the conductive layer 126. An upper end of the contact 65 is connected to the transfer gate line BLKSEL of the block BLK1 through the corresponding conductive layer of the plurality of conductive layers 66.

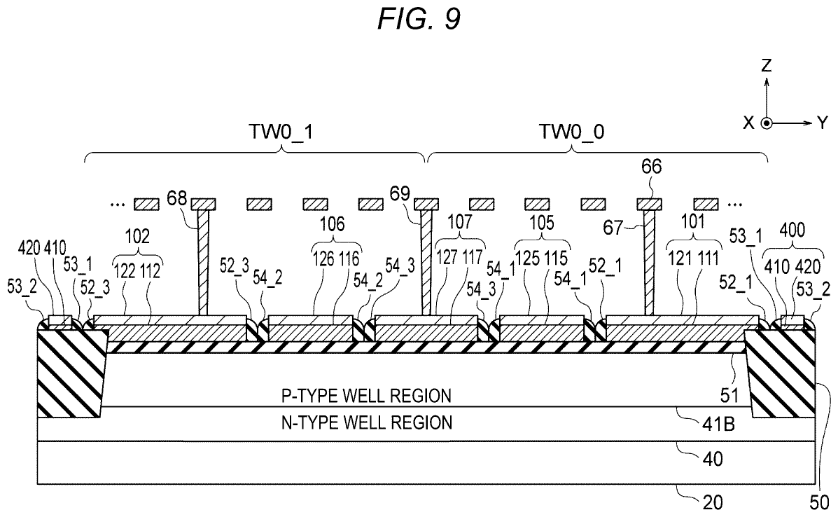

A cross-sectional structure of the transfer transistors TW0_0 and TW0_1 will be further described with reference to FIG. 9. FIG. 9 is a cross-sectional view taken along the line IX-IX of FIG. 7 and showing an example of a cross-sectional structure of the transfer transistor provided in the semiconductor memory device according to the embodiment. Hereinafter, a structure of the transfer transistor in the cross section shown in FIG. 9 will be described.

The gate insulating film 51 is provided on the P-type well region 41B over the entire region sandwiched by the insulator layer 50.

The conductive layer 111 is provided on an upper surface of a portion on one end side of the gate insulating film 51, and on an upper surface of a portion on the other side of the insulator layer 50 provided on one end side of the P-type well region 41B. The conductive layer 112 is provided on an upper surface of a portion on the other end side of the gate insulating film 51, and on an upper surface of a portion on one end side of the insulator layer 50 provided on the other end side of the P-type well region 41B.

In the cross section shown in FIG. 9, the second portion of the side wall 52_1 is in contact with the other end of the portion of the conductive layer 111 in the Y direction. A first portion of the side wall 54_1 is in contact with one end of the portion of the conductive layer 115 in the Y direction. A second portion of the side wall 52_1 and a first portion of the side wall 54_1 are in contact with each other along the Y direction.

Similarly, the second portion of the side wall 54_1 and the first portion of the side wall 54_3 are in contact with each other along the Y direction. A second portion of the side wall 54_3 and a first portion of the side wall 54_2 are in contact with each other along the Y direction. The second portion of the side wall 54_2 and the first portion of the side wall 52_3 are in contact with each other along the Y direction.

A lower end of the contact 67 is in contact with the conductive layer 121. An upper end of the contact 67 is electrically connected to the contact 61 through one of the conductive layers 66, as shown in FIGS. 7 and 9. Thereby, the conductive layer 121 (of electrode 101) is connected to the contact 61 to be at substantially the same potential.

A lower end of the contact 68 is in contact with the conductive layer 122. An upper end of the contact 68 is electrically connected to the contact 63 through one of the conductive layers 66, as shown in FIGS. 7 and 9. Thereby, the conductive layer 122 (of electrode 102) is connected to the contact 63 to be at substantially the same potential.

A lower end of the contact 69 is in contact with the conductive layer 127. An upper end of the contact 69 is electrically connected to the contact 62 through one of the conductive layers 66, as shown in FIGS. 7 and 9. Thereby, the conductive layer 127 (of electrode 107) is connected to the contact 62 to be at substantially the same potential.

### 1.2 Manufacturing Method of Transfer Transistor

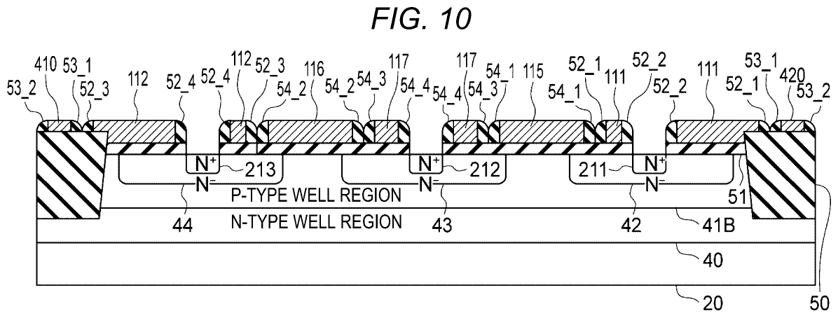

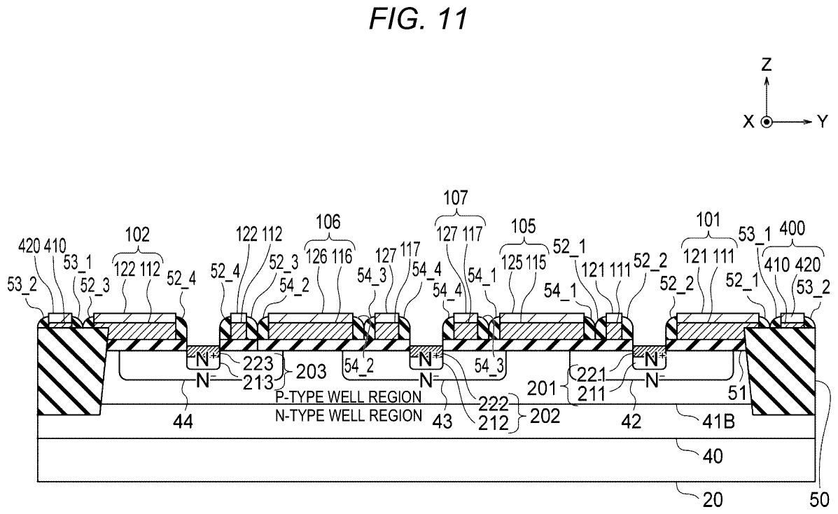

FIGS. 10 and 11 are cross-sectional views showing an example of a structure of the transfer transistor TW during manufacturing of the transfer transistor TW provided in the semiconductor memory device 1 according to the embodiment. The cross-sectional views shown in FIGS. 10 and 11 show a cross-sectional structure corresponding to FIG. 8. Hereinafter, an example of a manufacturing method related to the formation of the conductive layers 121, 122, 125, 126, 127, 420, 221, 222, and 223 will be mainly described.

As shown in FIG. 10, N-type impurities are selectively ion-implanted into the exposed N− impurity diffusion regions 42, 43, and 44 to form N+impurity diffusion regions 211, 212, and 213.

Thereafter, the salicide formation process is executed. By this processing, the electrodes 101, 102, 105, 106, 107, 201, 202, and 203 and the shield conductive layer 400 are formed as shown in FIG. 11.

More specifically, a metal film is stacked on the structure on which the N+ impurity diffusion regions 211, 212, and 213 are formed. The metal film is, for example, a film containing nickel (Ni), nickel platinum (NiPt), and cobalt (Co). Then, a portion of the metal film stacked outside a region where the transfer transistors TW, TS, and TD are to be provided in a plan view is removed by anisotropic etching using a pattern of a resist material. The anisotropic etching in this process is, for example, reactive ion etching (RIE). Then, the conductive layers 111, 112, 115, 116, 117, and 410 and the N+ impurity diffusion regions 211, 212, and 213, which are provided in the structure on which the metal film is formed, are subjected to heat treatment, so that the silicon contained in each of the conductive layers 111, 112, 115, 116, 117, and 410 and the N+ impurity diffusion regions 211, 212, and 213 and the metal element contained in the metal film react with each other. By the process, silicide (which is the material for the conductor layers 121, 122, 125, 126, 127, 420, 221, 222, and 223) is formed on the upper surfaces of each of the conductive layers 111, 112, 115, 116, 117, and 410 and the N+ impurity diffusion regions 211, 212, and 213. In addition, after the conductive layers 121, 122, 125, 126, 127, 420, 221, 222, and 223 are formed, the unreacted metal film is removed. As shown in FIG. 11, the conductive layers 121, 122, 125, 126, 127, 420, 221, 222, and 223 are formed on the upper surfaces of the conductive layers 111, 112, 115, 116, 117, and 410 and the N+ impurity diffusion regions 211, 212, and 213, respectively, by the salicide formation process.

As shown in FIG. 9, a region between the electrode 101 and the electrode 105 is closed by the side walls 52_1 and 54_1. A region between the electrode 105 and the electrode 107 is closed by the side walls 54_1 and 54_3. A region between the electrode 107 and the electrode 106 is closed by the side walls 54_3 and 54_2. A region between the electrode 106 and the electrode 102 is closed by the side walls 52_3 and 54_2. This is because the width Ws, which is the slit width in the Y direction between the adjacent electrodes 101, 102, 105, 106, and 107, is relatively small. Thereby, the entire surface salicide process can be applied to the region shown in FIG. 7.

### 1.3 Effect According to Embodiment

According to an embodiment, a decrease in reliability of a semiconductor memory device can be suppressed. Effects of the embodiment will be described below.

In the semiconductor memory device 1 according to the embodiment, the N− impurity diffusion regions 42, 43, and 44 are provided in the P-type well region 41B in this order along the Y direction, while being arranged to be separated from each other. The electrodes 201, 202, and 203 are provided in the N− impurity diffusion regions 42, 43, and 44, respectively. The electrode 201 functions as a first end of the transfer transistor TW0_0. The electrode 203 functions as a first end of the transfer transistor TW0_1. The electrode 202 functions as a second end of the transfer transistor TW0_0 and a second end of the transfer transistor TW0_1. The electrode 201 is connected to the word line WL0 of the block BLK corresponding to the transfer transistor TW0_0 through the contact 61. The electrode 202 is connected to the signal line CG0 through the contact 62. The electrode 203 is connected to the word line WL0 of the block BLK corresponding to the transfer transistor TW0_1 through the contact 63. An electrode 101 having an opening surrounding the contact 61 and an electrode 102 having an opening surrounding the contact 63 are provided above the P-type well region 41B. In addition, above the P-type well region 41B, the electrode 105 functioning as a gate of the transfer transistor TW0_0, the electrode 106 functioning as a gate of the transfer transistor TW0_1, and the electrode 107 having an opening surrounding the contact 62 are provided. With the structure of the electrodes 101, 102, 105, 106, and 107, the change in the characteristics of the transfer transistors TW0_0 and TW0_1 due to the change in the potential of each of the conductive layers 66 provided above the transfer transistors TW0_0 and TW0_1 can be prevented. Therefore, a decrease in reliability of the semiconductor memory device 1 can be suppressed.

In addition, when the conductive layer functioning as a gate is provided only between the adjacent N− impurity diffusion regions, for example, the resistance value of the N− impurity diffusion region is affected by the voltage change of the conductive layer (wiring) provided above the transistor. Such an influence may not be negligible, particularly in a transistor having a high breakdown voltage in which the resistance value of the N− impurity diffusion region is relatively high, from the viewpoint of the breakdown voltage and the reliability, which is not preferable. As a method for preventing the change in the resistance value of the N− impurity diffusion region, a method is known in which the wiring is provided at a high enough position with respect to the N− impurity diffusion region so that the influence can be ignored. However, when the method is used, the aspect ratio of the contact may be increased, so that it may be difficult to form the contact, and the characteristics of the semiconductor memory device may be deteriorated.

According to the semiconductor memory device 1 according to the embodiment, the electrode 101 surrounds the contact 61. In addition, the electrode 102 surrounds the contact 63. In addition, the electrodes 105 and 106 function as gates. In addition, the electrode 107 surrounds the contact 62. With such a configuration of the electrodes 101, 102, 105, 106, and 107, the electrodes 101 and 102 can cover the entire upper surfaces of the N− impurity diffusion regions 42, 43, and 44. Further, during various operations such as the write operation, the read operation, and the erasing operation, a voltage equal to or higher than the ground voltage VSS is applied to each of the electrodes 101, 102, 105, 106, and 107. From these, the electrodes 101, 102, 105, 106, and 107 can shield the electric field formed by the conductive layers 66. Therefore, during various operations such as a write operation, a read operation, and an erasing operation, it is possible to prevent the change in the resistance values of the N− impurity diffusion regions 42, 43, and 44 due to the change in the potential of the conductive layer 66. Therefore, even when the resistance value of the N− impurity diffusion region is relatively high, it is possible to prevent the aspect ratio of the contact from increasing and to prevent the reliability of the transfer transistors TW0_0 and TW0_1 from decreasing due to the change in the potential of each conductive layer 66.

Further, according to the embodiment, the transfer transistors TW0_0 and TW0_1 share the electrode 202. With such a configuration, an area occupied by the transfer transistors TW0_0 and TW0_1 on the semiconductor substrate 20 can be decreased. Therefore, the size of the semiconductor memory device 1 can be decreased.

Further, according to the embodiment, it is possible to suppress the decrease in reliability of the semiconductor memory device by improving a surface breakdown voltage. The surface breakdown voltage is a breakdown voltage that occurs in the pn junction between the source or the drain and the well region (which is in the semiconductor substrate) near the gate when a high potential difference occurs between the gate and the source or the drain in a state where 0 V is applied to the gate.

The electrodes 101, 102, and 107 are at substantially the same potential as the contacts 61, 63, and 62, respectively, and are not used as gates. Thereby, even when 0 V is applied to the electrodes 105 and 106 serving as the gates, the electric field concentration in the well region near the contacts 61, 62, and 63 can be reduced. As a result, the surface breakdown voltage can be improved. Therefore, the surface breakdown voltage of the transfer transistors TW0_0 and TW0_1 can be improved while suppressing a decrease in the reliability of the transfer transistors TW0_0 and TW0_1 due to the change in the potential of the conductive layer 66.

### 2. Modification Examples

The above-described embodiment can be modified in various ways.

A semiconductor memory device according to modification examples will be described below. Hereinafter, a configuration and a manufacturing method of a semiconductor memory device according to the modification example will be described with a focus on the points different from the semiconductor memory device 1 according to the embodiment. The semiconductor memory device according to the modification example also achieves the same effect as the embodiment.

### 2.1 First Modification Example

In the above-described embodiment, a position of the slit between the electrode 101 and the electrode 105 may be changed.

In the following description, a configuration of the transfer transistor according to the first modification example will be mainly described with a configuration different from the configuration of the embodiment.

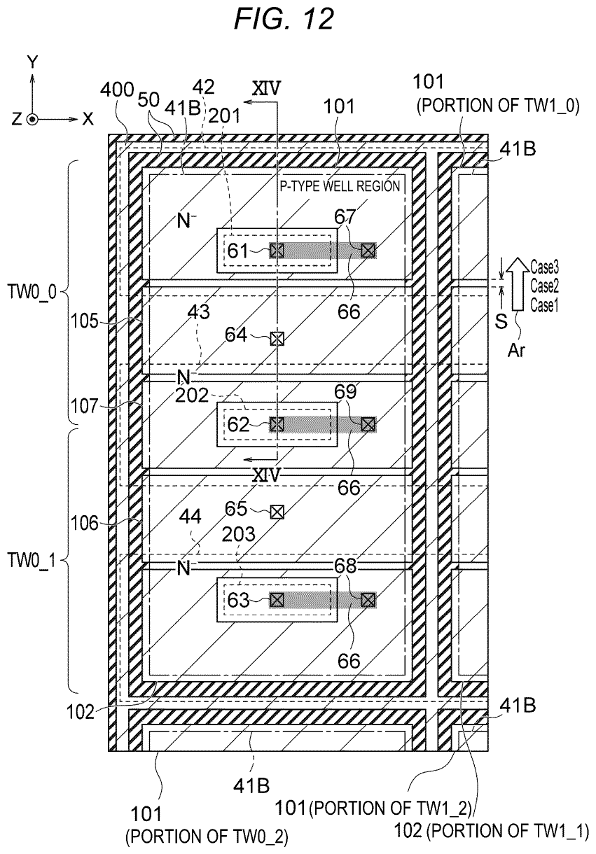

A planar structure of the transfer transistors TW0_0 and TW0_1 according to the first modification example will be described with reference to FIG. 12. FIG. 12 is a plan view showing an example of a planar structure of a transfer transistor provided in the semiconductor memory device according to the first modification example.

In the example shown in FIG. 12, the N− impurity diffusion regions 42, 43, and 44 are also disposed around the P-type well region 41B, for example. Specifically, when viewed in the Z direction, the end portion of the N− impurity diffusion region 42 is disposed outside the end portions of the P-type well region 41B in the +X direction, the −X direction, and the +Y direction. When viewed in the Z direction, the end portion of the N− impurity diffusion region 43 is disposed outside the end portions of the P-type well region 41B in the +X direction and the −X direction. When viewed in the Z direction, the end portion of the N− impurity diffusion region 44 is disposed outside the end portions of the P-type well region 41B in the +X direction, the −X direction, and the −Y direction. That is, when viewed in the Z direction, the P-type well region 41B straddle the N− impurity diffusion regions 42, 43, and 44. In addition, the N− impurity diffusion region 42 may be disposed to be shared by the transfer transistors TW0_0 and TW1_0 adjacent to each other in the X direction. Similarly, the N− impurity diffusion region 43 may be disposed to be shared by the transfer transistors TW0_0 and TW1_0 adjacent to each other in the X direction and may be shared by the transfer transistors TW0_1 and TW1_1 adjacent to each other in the X direction. Similarly, the N− impurity diffusion region 44 may be disposed to be shared by the transfer transistors TW0_1 and TW1_1 adjacent to each other in the X direction.

The electrodes 101 and 105 are provided such that the slit S between the electrode 101 and the electrode 105 is shifted in a direction opposite to the channel between the N− impurity diffusion region 42 and the N− impurity diffusion region 43 (the +Y direction in FIG. 12). That is, the slit S is shifted in a direction of the arrow Ar.

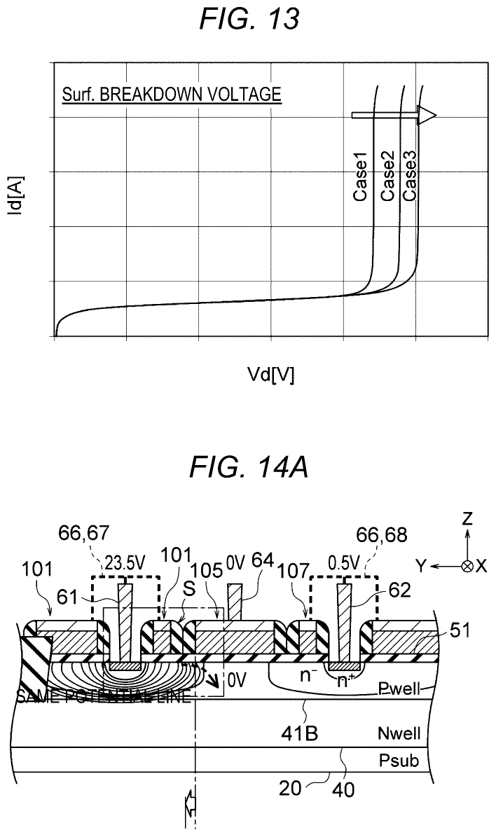

FIG. 13 is a graph showing an example of the surface breakdown voltage of the transfer transistor according to the first modification example. The horizontal axis indicates a drain voltage. The vertical axis indicates a drain current. The graph shows data of Case1, Case2,and Case3. Case1, Case2, and Case3 are data in which the shift of the position of the slit S is increased in this order.

The surface breakdown voltage is improved from Case1 to Case3, that is, as the shift of the position of the slit S increases.

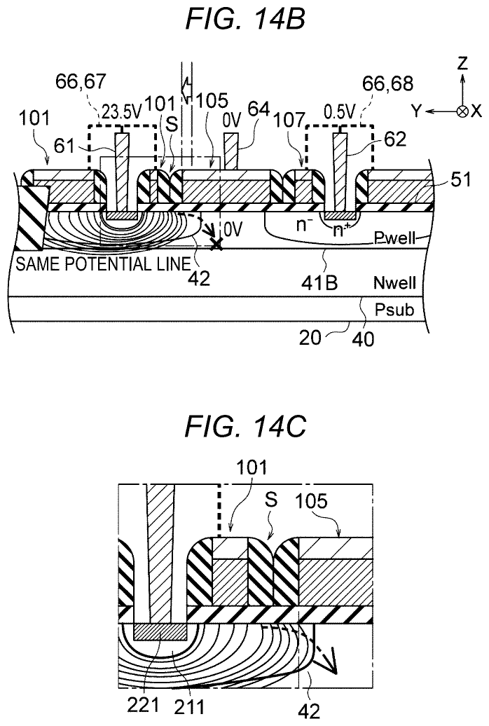

The potential gradient and the surface breakdown voltage will be described with reference to FIGS. 14A-14D. FIGS. 14A and 14B are cross-sectional views taken along the line XIV-XIV of FIG. 12 and show an example of a cross-sectional structure of the transfer transistor provided in the semiconductor memory device according to the first modification example. In FIGS. 14A and 14B, the left and right are shown in reverse as compared to FIG. 8. FIG. 14A shows a case where the shift of the position of the slit S is small as in Case 1. FIG. 14B shows a case where the shift of the position of the slit S is large as in Case 3. In addition, each of FIGS. 14C and 14D shows an enlarged view of the one-dot chain line frame shown in FIGS. 14A and 14B.

In FIGS. 14B and 14D, the shift of the position of the slit S is larger than that in FIGS. 14A and 14C. As a result, in FIGS. 14B and 14D, the width of the electrode 101 in the Y direction is smaller than that in FIGS. 14A and 14C. That is, in FIGS. 14B and 14D, the width Wg is smaller than that in FIGS. 14A and 14C. In addition, in FIGS. 14B and 14D, the overlap between the electrode 105 and the N− impurity diffusion region 42 along the Y direction is larger than that in FIGS. 14A and 14C. That is, in FIGS. 14B and 14D, the overlap distance L is longer than that in FIGS. 14A and 14C.

FIGS. 14A to 14D show an example of a data erasing operation of the semiconductor memory device 1. For example, a voltage of 23.5 V is applied to the contact 61. A voltage of 0 V (which is the cutoff voltage) is applied to the contact 64. A voltage of 0.5 V is applied to the contact 62.

FIGS. 14A to 14D schematically show equipotential lines with respect to electric field lines from a contact point between the contact 61 and the semiconductor substrate 20.

In FIGS. 14A and 14C, the potential difference is large in the vicinity of the electrode 105 by the electrode 105 of 0 V. That is, the equipotential lines near the electrode 105 become dense. In a region where the equipotential lines are dense, a high electric field may be generated, and surface leakage may occur. The surface leakage is indicated by a broken line arrow and is a leakage to the P-type well region 41B of the semiconductor substrate 20 at 0 V.

In FIGS. 14B and 14D, the overlap between the electrode 105 and the N− impurity diffusion region 42 is expanded (the overlap distance L is extended) by shifting the slit S. That is, the N− impurity diffusion region 42 overlapping the electrode 105 in the Z direction increases, so that the voltage drop amount in the N− impurity diffusion region 42 overlapping with the electrode 105 in the Z direction, which is the gate, is increased. As a result, the surface leakage can be reduced by reducing the potential difference between one end side of the electrode 105 and the other end side of the N-type impurity diffusion region 42 at the junction portion. That is, the surface breakdown voltage may be improved.

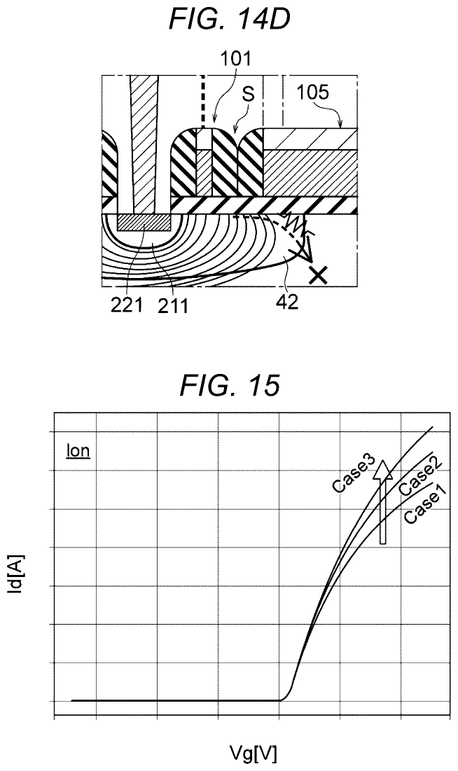

FIG. 15 is a graph showing an example of an on-current of the transfer transistor according to the first modification example. The horizontal axis indicates a gate voltage. The vertical axis indicates a drain current. The graph shows data of Case1, Case2, and Case3. Case1, Case2, and Case3 are data in which the shift of the position of the slit S is increased in this order.

The on-current is improved from Case 1 to Case 3, that is, as the shift of the position of the slit S increases. This is because the larger the overlap between the electrode 105 and the N− impurity diffusion region 42 in the Y direction when viewed from the Z direction, the larger the on-current.

The electrodes 102 and 106 may be provided such that the slit between the electrode 102 and the electrode 106 are shifted in a direction opposite to the channel between the N− impurity diffusion region 43 and the N− impurity diffusion region 44 (the −Y direction in FIG. 12), not limited to the electrodes 101 and 105.

The same effects as those of the embodiment can be obtained by the configuration of the transfer transistor as described above.

### 2.2 Second Modification Example

In the above-described embodiment, a part of the electrodes 101 and 102 may be cut.

In the following description, a configuration of the transfer transistor according to the second modification example will be mainly described with a configuration different from the configuration of the embodiment.

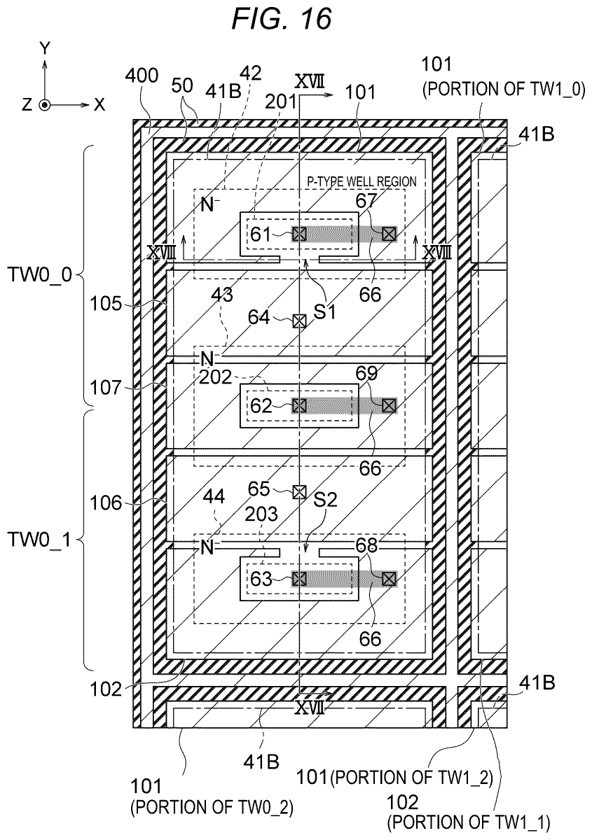

A planar structure of the transfer transistors TW0_0 and TW0_1 according to the second modification example will be described with reference to FIG. 16. FIG. 16 is a plan view showing an example of a planar structure of a transfer transistor provided in the semiconductor memory device according to the second modification example.

The electrode 101 has a slit S1 that reaches the opening from the end portion of the electrode 101 facing the electrode 105. That is, the inner periphery of the electrode 101 is connected to the outer periphery of the electrode 101. In addition, the opening of the electrode 101 is connected to a slit between the electrode 101 and the electrode 105.

The electrode 102 has a slit S2 that reaches the opening from the end portion of the electrode 102 facing the electrode 106. That is, the inner periphery of the electrode 102 is connected to the outer periphery of the electrode 102. In addition, the opening of the electrode 102 is connected to a slit between the electrode 102 and the electrode 106.

The opening of the electrode 107 may be connected to a slit between the electrode 107 and the electrode 105. The opening of the electrode 107 may be connected to a slit between the electrode 107 and the electrode 106.

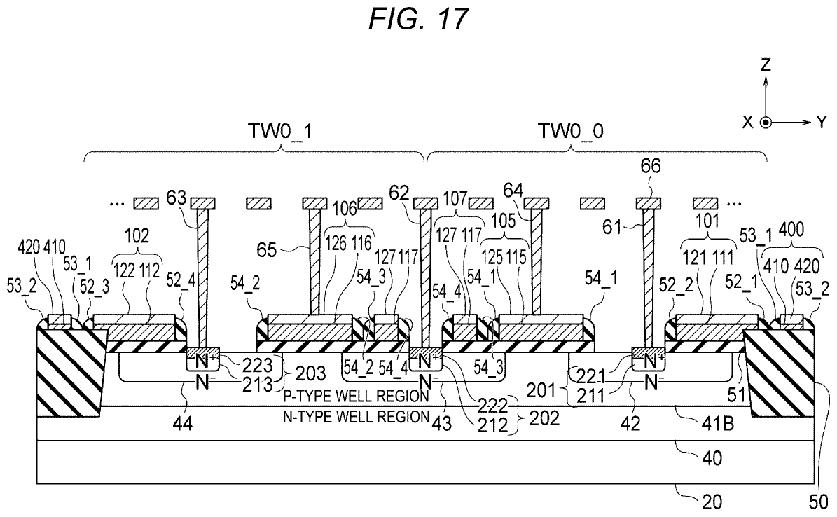

A cross-sectional structure of the transfer transistors TW0_0 and TW0_1 according to the second modification example will be described with reference to FIG. 17. FIG. 17 is a cross-sectional view taken along the line XVII-XVII of FIG. 16 and showing an example of a cross-sectional structure of the transfer transistor provided in the semiconductor memory device according to the second modification example.

As shown in FIG. 17, in the second modification example, the portion of the electrode 101 provided on the other end side than the electrode 201 is not provided. In addition, the portion of the electrode 102 provided on one end side with respect to the electrode 203 is not provided.

The same effects as those of the embodiment and the first modification example can be obtained by the configuration of the transfer transistor as described above.

In the second modification example, the characteristics of the surface breakdown voltage and the on-current are substantially the same as those in the embodiment, as compared with the embodiment.

Further, in the second modification example, the electrode 101 has a slit S1. The electrode 102 has a slit S2. That is, the opening of the electrode 101 is connected to a slit between the electrode 101 and the electrode 105, and the opening of the electrode 102 is connected to a slit between the electrode 102 and the electrode 106. Therefore, in the second modification example as compared with the embodiment, the manufacturing of the semiconductor memory device 1 is easy even when the width Ws of the slit is small.

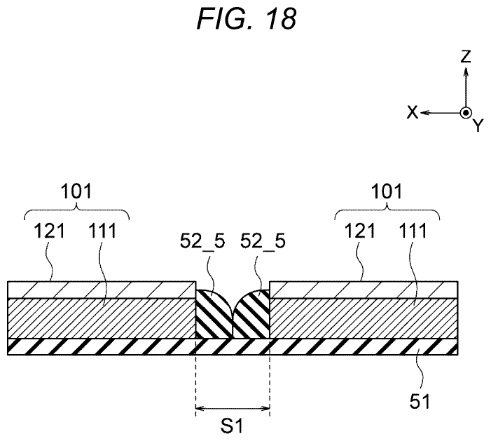

In addition, the cross-sectional structures of the transfer transistors TW0_0 and TW0_1 according to the second modification example will be described with reference to FIG. 18. FIG. 18 is a cross-sectional view taken along the line XVIII-XVIII of FIG. 16 and showing an example of a cross-sectional structure of the transfer transistor provided in the semiconductor memory device according to the second modification example. In FIG. 18, the configuration other than the gate insulating film 51, the electrode 101, and the side wall 52_5 is omitted.

As shown in FIG. 18, a region of the slit S1 may be closed by the side wall 52_5 provided on the side surface of the electrode 101 in the X direction. Similarly, a region of the slit S2 (not shown) may be closed by a side wall provided on the side surface of the electrode 102 in the X direction.

### 2.3 Third Modification Example

Although the above-described embodiment shows an example in which the electrode 107 and the contact 69 are provided, the present disclosure is not limited to these. The electrode 107 and the contact 69 may not be provided.

In the following description, a configuration of the transfer transistor according to the third modification example will be mainly described with a configuration different from the configuration of the embodiment.

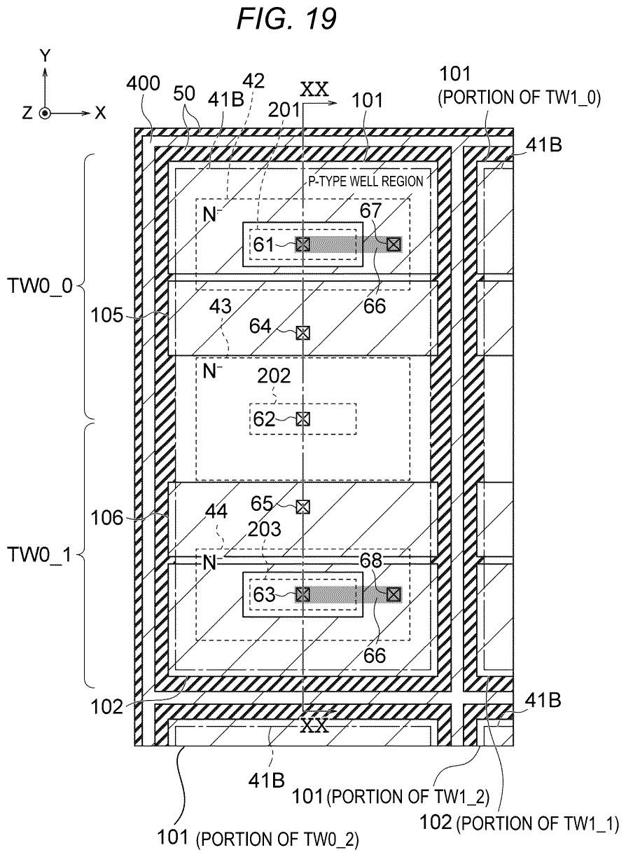

A planar structure of the transfer transistors TW0_0 and TW0_1 according to the third modification example will be described with reference to FIG. 19. FIG. 19 is a plan view showing an example of a planar structure of a transfer transistor provided in the semiconductor memory device according to the third modification example.

As shown in FIG. 19, the electrode 107 is not provided in the third modification example. Therefore, the structures of the drain side and the source side of the transfer transistor TW are different. That is, the structure is asymmetric on the drain side and the source side of the transfer transistor TW. The electrode 107 is not provided on the other end side of the transfer transistor TW0_0, that is, the drain side. Meanwhile, the electrode 101 is provided on one end side of the transfer transistor TW0_, that is, on the source side. The electrode 107 is not provided on the one end side of the transfer transistor TW0_1, that is, the drain side. Meanwhile, the electrode 102 is provided on the other end side of the transfer transistor TW0_1, that is, the source side.

The electrode 105 and the N− impurity diffusion region 43 do not overlap with each other when viewed in the Z direction. In addition, the end portion of the electrode 105 and the outer peripheral end portion of the N− impurity diffusion region 43 are substantially flat when viewed in the Z direction. In addition, the electrode 106 and the N− impurity diffusion region 43 do not overlap with each other when viewed in the Z direction. In addition, the end portion of the electrode 106 and the outer peripheral end portion of the N− impurity diffusion region 43 are substantially flat when viewed in the Z direction. Thereby, the surface breakdown voltage may be further improved.

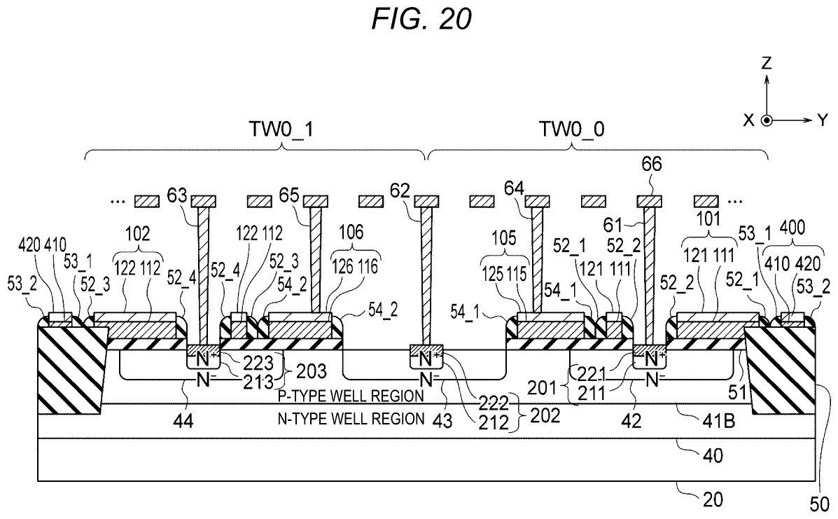

A cross-sectional structure of the transfer transistors TW0_0 and TW0_1 according to the third modification example will be described with reference to FIG. 20. FIG. 20 is a cross-sectional view taken along the line XX-XX of FIG. 19 and showing an example of a cross-sectional structure of the transfer transistor provided in the semiconductor memory device according to the third modification example.

As shown in FIG. 20, the N− impurity diffusion region 43 is not covered with the electrode 107.

The same effects as those of the embodiment, the first modification example, and the second modification example can be obtained even with the configuration of the transfer transistor as described above.

The third modification example can be applied to a portion where, for example, the surface breakdown voltage requirement is not strict on the N− impurity diffusion region 42 side and a high cutoff characteristic is required on the N− impurity diffusion region 43 side. That is, although the structure of the transfer transistor TW provided in the row decoder RD is described as an example in FIGS. 19 and 20, the third modification example may be applied to, for example, a peripheral circuit, a voltage boosting circuit, or the like.

### 2.4 Fourth Modification Example

Although the above-described embodiment shows an example in which the silicide block film is not provided, the present disclosure is not limited to these. A silicide block film may be provided.

In the following description, a configuration of the transfer transistor according to the fourth modification example will be mainly described with a configuration different from the configuration of the third modification example.

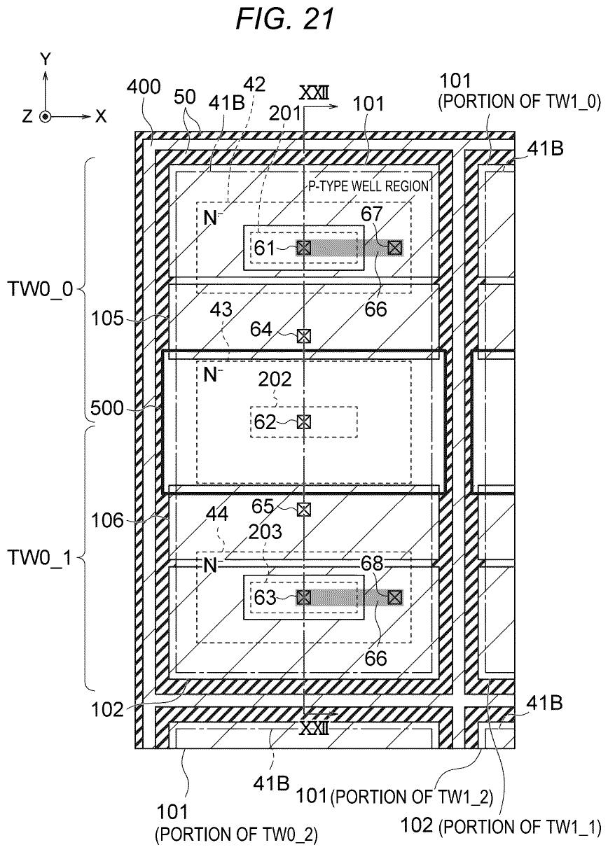

A planar structure of the transfer transistors TW0_0 and TW0_1 according to the fourth modification example will be described with reference to FIG. 21. FIG. 21 is a plan view showing an example of a planar structure of a transfer transistor provided in the semiconductor memory device according to the fourth modification example.

As shown in FIG. 21, a silicide block film 500 that prevents silicidation is provided in a region near the electrode 202 when viewed in the Z direction, so that the P-type well region 41B is not silicidized.

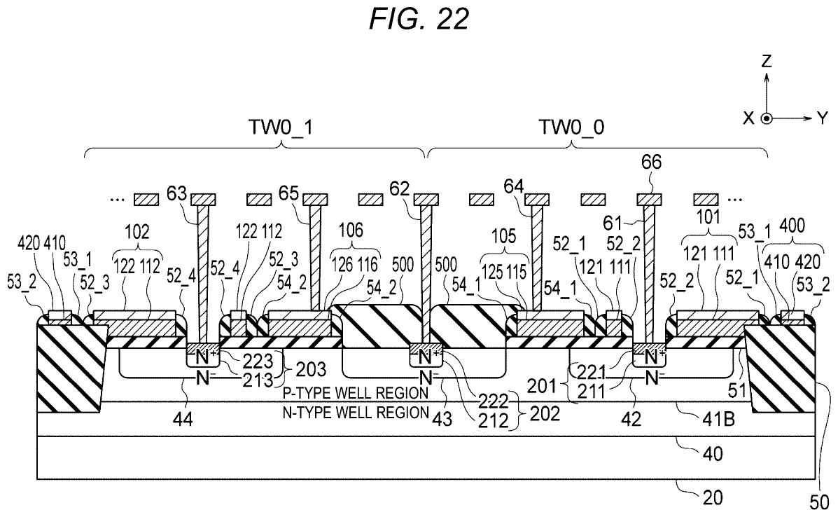

A cross-sectional structure of the transfer transistors TW0_0 and TW0_1 according to the fourth modification example will be described with reference to FIG. 22. FIG. 22 is a cross-sectional view taken along the line XXII-XXII of FIG. 21 and shows an example of a cross-sectional structure of the transfer transistor provided in the semiconductor memory device according to the fourth modification example.

As shown in FIG. 22, the silicide block film 500 is provided on the upper surface of the P-type well region 41B. A part of the silicide block film 500 is provided on a part of the upper surface of the electrodes 105 and 106.

### 2.5 Fifth Modification Example

Although the above-described embodiment shows an example in which the end portions of the electrodes 101, 102, 105, 106, and 107 are provided outside the P-type well region 41B, the present disclosure is not limited thereto. The end portions of the electrodes 101, 102, 105, 106, and 107 may be provided inside the P-type well region 41B.

In the following description, a configuration of the transfer transistor according to the fifth modification example will be mainly described, which is different from the configuration of the embodiment.

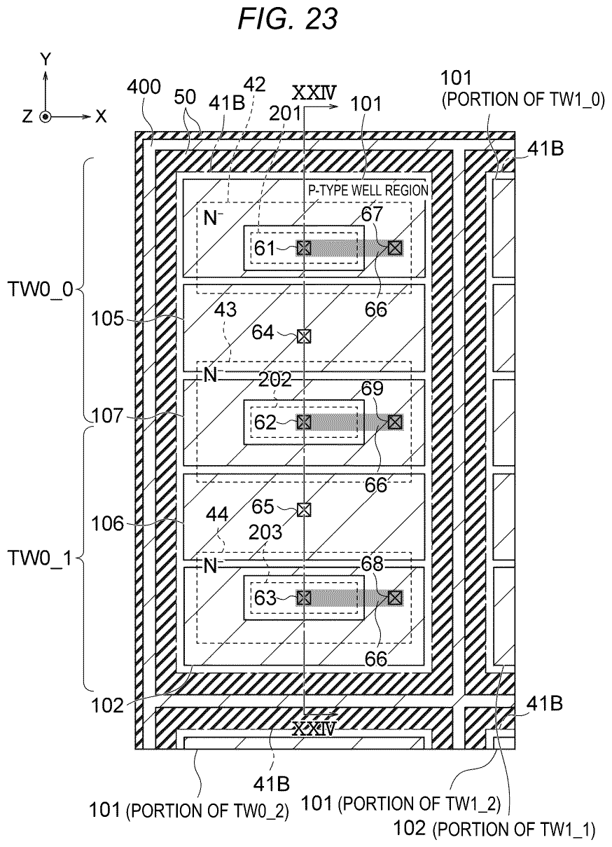

A planar structure of the transfer transistors TW0_0 and TW0_1 according to the fifth modification example will be described with reference to FIG. 23. FIG. 23 is a plan view showing an example of a planar structure of a transfer transistor provided in the semiconductor memory device according to the fifth modification example.

The electrodes 101, 102, 105, 106, and 107 are provided inside the P-type well region 41B provided on the semiconductor substrate 20 when viewed in the Z direction.

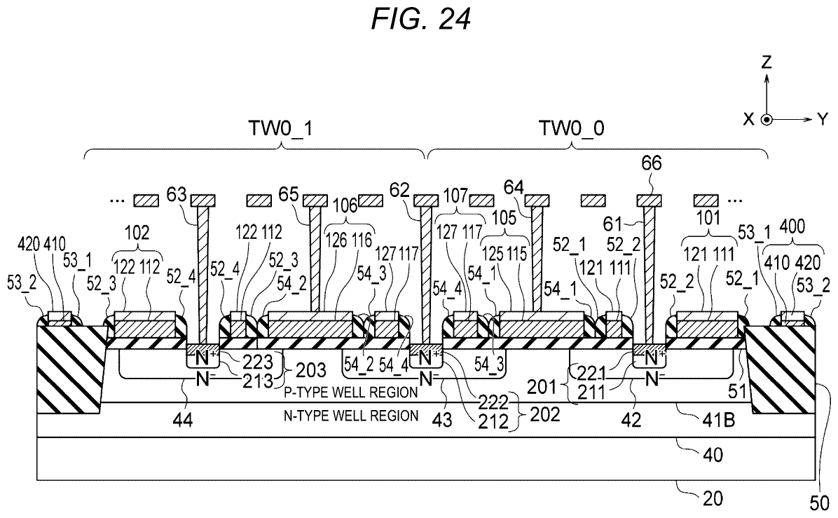

A cross-sectional structure of the transfer transistors TW0_0 and TW0_1 according to the fifth modification example will be described with reference to FIG. 24. FIG. 24 is a cross-sectional view taken along the line XXIV-XXIV of FIG. 23 and shows an example of a cross-sectional structure of the transfer transistor provided in the semiconductor memory device according to the fifth modification example.

The electrodes 101 and 102 do not reach the insulator layer 50 (do not come into contact with the insulator layer 50). That is, the electrode 101 is provided on the other end side of the insulator layer 50. In addition, the electrode 102 is provided on one end side of the insulator layer 50. Thereby, the distance between the electrodes of the transfer transistor TW0_0 and the transfer transistor TW0_1 and the electrodes of the transfer transistor TW1_0 and the transfer transistor TW1_1 can be increased. Therefore, it is possible to suppress the leakage between adjacent elements such as field-inversion leakage and punch-through leakage.

The same effects as those of the embodiment, the first modification example, the second modification example, the third modification example, and the fourth modification example can be obtained even with the configuration of the transfer transistor as described above.

### 2.6 Sixth Modification Example

Although the fifth modification example described above shows an example in which the end portions of the electrodes 101, 102, 105, 106, and 107 are provided inside the P-type well region 41B, the present disclosure is not limited thereto. A part of the end portions of the electrodes 105 and 106 may be provided outside the P-type well region 41B.

In the following description, a configuration of the transfer transistor according to the sixth modification example will be mainly described with a configuration different from the configuration of the fifth modification example.

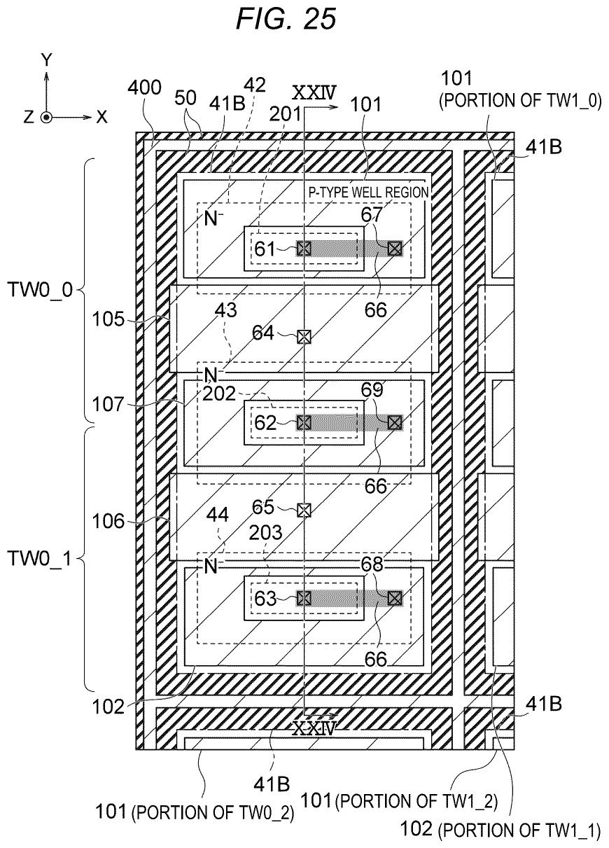

A planar structure of the transfer transistors TW0_0 and TW0_1 according to the sixth modification example will be described with reference to FIG. 25. FIG. 25 is a plan view showing an example of a planar structure of a transfer transistor provided in the semiconductor memory device according to the sixth modification example.

The electrodes 101, 102, and 107 are provided inside the P-type well region 41B provided on the semiconductor substrate 20 when viewed in the Z direction. The electrodes 105 and 106 extend in the X direction from the P-type well region 41B when viewed in the Z direction. That is, in the X direction, a part of the electrode 105 and the electrode 106 are provided outside the P-type well region 41B. Thereby, the area in which the electrode 105 and the electrode 106 overlap with the P-type well region 41B is increased in the view from the Z direction, and it is possible to prevent the leakage from the P-type well region 41B to the adjacent element. Therefore, the stability of the characteristics of the transfer transistors TW_0 and TW0_1 can be improved when the current is cut off or the like.

The same effects as those of the embodiments, the first modification example, the second modification example, the third modification example, the fourth modification example, and the fifth modification example can be obtained even with the configuration of the transfer transistor as described above.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a semiconductor substrate that includes a well region of a first conductivity-type and first, second, and third regions of a second conductivity-type arranged in this order and spaced apart from each other in a first direction in this order on the well region, wherein each of the first, second, and third regions is a source region or a drain region;
a first conductive layer that is provided above the well region and has a first opening;
a second conductive layer that is provided above the well region, has a second opening, and is spaced apart from the first conductive layer in the first direction;
a first contact that is connected to the first region and passes through the first opening;
a second contact that is connected to the third region and passes through the second opening;
a first memory cell that is connected to the first contact;
a second memory cell that is connected to the second contact; and
a third conductive layer and a fourth conductive layer that are provided between the first conductive layer and the second conductive layer above the well region, and are spaced apart from each other in the first direction,
wherein the third conductive layer is between the first conductive layer and the fourth conductive layer and spaced apart from the first conductive layer,
the fourth conductive layer is between the second conductive layer and the third conductive layer and spaced apart from the second conductive layer,
the first conductive layer and the first contact are connected to each other to be at substantially the same potential, and
the second conductive layer and the second contact are connected to each other to be at substantially the same potential.

2. The semiconductor memory device according to claim 1, further comprising:
a third contact that is connected to the second region and passes through between the third conductive layer and the fourth conductive layer.

3. The semiconductor memory device according to claim 2, further comprising:
a fifth conductive layer that is provided between the third conductive layer and the fourth conductive layer above the well region, and has a third opening through which the third contact passes,
wherein the fifth conductive layer is spaced apart from the third conductive layer and the fourth conductive layer, and
the fifth conductive layer and the third contact are connected to each other to be at substantially the same potential.

4. The semiconductor memory device according to claim 3,
wherein the first conductive layer has a first slit that is connected to the first opening from an end portion of the first conductive layer facing the third conductive layer, and
the second conductive layer has a second slit that is connected to the second opening from an end portion of the second conductive layer facing the fourth conductive layer.

5. The semiconductor memory device according to claim 3,
wherein the first conductive layer, the second conductive layer, the third conductive layer, the fourth conductive layer, and the fifth conductive layer are disposed inside the well region provided in the semiconductor substrate, when viewed from a direction substantially perpendicular to the semiconductor substrate.

6. The semiconductor memory device according to claim 3,
wherein the first conductive layer, the second conductive layer, and the fifth conductive layer are provided inside the well region provided in the semiconductor substrate, when viewed in a direction substantially perpendicular to the semiconductor substrate, and
the third conductive layer and the fourth conductive layer extend in a second direction substantially perpendicular to the first direction and substantially parallel to the semiconductor substrate outside the well region, when viewed in the direction substantially perpendicular to the semiconductor substrate.

7. The semiconductor memory device according to claim 2,
wherein the third conductive layer and the second region do not overlap with each other when viewed in a direction substantially perpendicular to the semiconductor substrate, and the fourth conductive layer and the second region do not overlap with each other when viewed in the direction substantially perpendicular to the semiconductor substrate.

8. The semiconductor memory device according to claim 1,
wherein the first region and the third conductive layer overlap with each other when viewed in a direction substantially perpendicular to the semiconductor substrate.

9. The semiconductor memory device according to claim 8,
wherein the first region and the third conductive layer overlap with each other in a range of 0.2 μm to 0.6 μm in the first direction when viewed in a direction substantially perpendicular to the semiconductor substrate.

10. The semiconductor memory device according to claim 1, wherein the first conductivity-type is a P-type conductivity, and the second conductivity-type is an N-type conductivity.

11. A semiconductor memory device comprising:
a first memory cell having a gate connected to a first word line;
a second memory cell having a gate connected to a second word line;
a first transfer transistor connected between the first word line and a signal line;
a second transfer transistor connected between the second word line and the signal line;
first, second, third, fourth, and fifth generally planar electrodes arranged in this order and spaced apart in a first direction, and having an upper surface at a same level above a substrate, wherein the second electrode is a gate electrode of the first transfer transistor and the fourth electrode is a gate electrode of the second transfer transistor;
a first diffusion region separately provided for each of the first and second transfer transistors, and a second diffusion region provided in common for both the first and second transfer transistors;
a first contact extending in a second direction perpendicular to the first direction and a surface of the substrate and connected to an electrode in the first diffusion region of the first transfer transistor and the first word line;
a second contact extending in the second direction and connected to an electrode in the first diffusion region of the second transfer transistor and the second word line; and
a third contact extending in the second direction and connected to an electrode in the common second diffusion region of the first and second transfer transistors and the signal line, wherein
the first, third, and fifth electrodes have respective first, third, and fifth openings that are aligned in the first direction and extend in the second direction, and
the first, second, and third contacts are respectively disposed in the first, fifth, and third openings and respectively connected to the first, fifth, and third electrodes to be at substantially the same potential as the respective first, fifth, and third electrodes.

12. The semiconductor memory device according to claim 11, wherein the substrate is a semiconductor substrate that includes a well region and the diffusion regions are formed on the well region.

13. The semiconductor memory device according to claim 12, wherein the first electrode and the second electrode overlap the first diffusion region of the first transfer transistor in the second direction, and the fourth electrode and the fifth electrode overlap the first diffusion region of the second transfer transistor in the second direction.

14. The semiconductor memory device according to claim 13, wherein the second, third, and fourth electrodes overlap the common second diffusion region of the first and second transfer transistors in the second direction.

15. The semiconductor memory device according to claim 13,
wherein the first, second, third, fourth, and fifth conductive layers are disposed inside the well region when viewed from the second direction.

16. The semiconductor memory device according to claim 13,
wherein the first conductive layer, the third conductive layer, and the fifth conductive layer are provided inside the well region when viewed in the second direction, and
the second conductive layer and the fourth conductive layer extend in a third direction that is perpendicular to the first and second directions, outside the well region when viewed in the second direction.

17. The semiconductor memory device according to claim 11, wherein adjacent electrodes of the first, second, third, fourth, and fifth electrodes are separated by insulating sidewalls formed on side surfaces of the adjacent electrodes.

18. The semiconductor memory device according to claim 11,
wherein the first conductive layer has a first slit that is connected to the first opening from an end portion of the first conductive layer facing the second conductive layer, and
the fifth conductive layer has a second slit that is connected to the fifth opening from an end portion of the fifth conductive layer facing the fourth conductive layer.

19. The semiconductor memory device according to claim 11, wherein each electrode in the diffusion regions includes a silicide layer that is in direct contact with the corresponding one of the first, second, and third contacts.

20. The semiconductor memory device according to claim 11, wherein each of the first. second, third, fourth, and fifth electrodes includes a lower electrode layer and an upper electrode layer that is a silicide layer.
